(19) United States
(12) Patent Application Publication
(10) Pub. No.: US 2012/0312956 A1
(43) Pub. Date: Dec. 13, 2012

(54) LIGHT SENSOR SYSTEM FOR OBJECT DETECTION AND GESTURE RECOGNITION, AND OBJECT DETECTION METHOD

(76) Inventors: Tom Chang, Taipei City (TW); Kao Pin Wu, New Taipei City (TW); Chih Jen Fang, Tainan City (TW); Cheng Te Chan, New Taipei City (TW); Cheng Ta Chuang, New Taipei City (TW); Fang Yu Liu, Hsinchu County (TW)

(21) Appl. No.: 13/494,000

(22) Filed: Jun. 11, 2012

Related U.S. Application Data
(60) Provisional application No. 61/495,960, filed on Jun. 11, 2011.

(51) Int. Cl. H01L 31/00

(52) U.S. Cl. 250/201.1; 250/214.1; 250/208.2; 250/206.2

(57) ABSTRACT

A light sensor system includes at least one light emitter, a light sensor unit and a processing unit. The light sensor unit is arranged to receive reflected light from an object in accordance with a time sequence in which the at least one light emitter is activated, and accordingly output a plurality of reflected signals. The processing unit is arranged to receive the reflected signals, identify a signal function of time by referring to occurrence sequence of local peak levels of the reflected signals, and determine motion of the object according to the signal function of time. Another light sensor system is proposed. The major difference between the two light sensor systems is that the processing unit of the another light sensor system is arranged to identify the signal function of time by comparing a predetermined threshold with signal levels of the reflected signals.

### CROSS REFERENCE TO RELATED APPLICATIONS

This application claims the benefit of U.S. provisional application No. 61/495,960, “MULTI-DIMENSIONAL REFLECTANCE-BASED INFRARED PROXIMITY LIGHT SENSOR SYSTEM AND METHOD FOR HAND GESTURE DETECTION AND RECOGNITION”, which was filed on Jun. 11, 2011. The entire content of the related application is incorporated herein by reference.

### BACKGROUND OF THE INVENTION

1. Field of the Invention

The present invention relates to gesture detection and recognition, and more particularly, to a light sensor system for detecting an object (e.g. a user's hand) which can recognize gestures to thereby control electronic devices, and a related object detection method.

2. Description of the Prior Art

Touch screen sensors are used in a wide variety of applications, including mobile devices, computer monitors, smart phones, laptop PCs, tablet PCs, computer work stations, appliances, medical equipment, machinery, etc. The technologies used for such touch screen sensors include resistive, capacitive, acoustic and optical. None of the prior art touch screen technologies, however, has demonstrated the ability to detect and recognize a wide variety of hand gestures which are in proximity to but not in direct contact with the screen.

The applications for non-direct contact hand gesture detection and recognition, or screen pointing, are numerous. For example, one such application is when directly touching the screen may contaminate the screen or the user—such as when the user is handling foods, greasy mechanical parts or the like that can cause the screen to look dirty after being touched. Another example is in hospitals, clinics or other public places, when a touch screen touched by many users' hands may present a path for transmitting germs or disease.

Yet another example of an application for non-direct contact hand gesture detection and recognition is when the user is wearing gloves. Gloved fingers do not work well with capacitive touch screen sensors. For example, capacitive touch screen sensors have limited capability to pick up a signal when the cover lens is thicker than a few millimeters, such as the window glass of a retail store, or a glass table top in a restaurant. One additional application for non-direct contact hand gesture detection and recognition is for electronic kiosks, games and children's learning systems where such a feature can provide more functionality and entertainment.

A conventional touch system uses a camera sensor, installed near the screen and facing the user, to record images of the user's gestures and to recognize the user's gestures by image signal processing techniques. Such conventional camera sensor systems involve substantial hardware costs and power to process image recognition. Moreover, these conventional camera sensor systems do not measure the distance between the sensor and the user's hand, so there is limited capability to recognize a change in the Z-direction (for these purposes, the “Z” direction means the direction near-or-away from the sensor, or normal to the plane of the sensor).

Therefore, what is needed is a multi-dimensional light sensor system and method for hand gesture detection and recognition that can allow for accurate, reliable and flexible hand gesture detection and recognition across a wide variety of applications without the need for the user to touch the screen.

### SUMMARY OF THE INVENTION

In accordance with exemplary embodiments of the present invention, a light sensor system for detecting an object (e.g. a user's hand) and recognizing gestures thereof for controlling electronic devices, and related object detection method are proposed to solve the above-mentioned problem.

According to an embodiment of the present invention, an exemplary light sensor system is disclosed. The exemplary light sensor system comprises at lease one light emitter, a light sensor unit and a processing unit. The light sensor unit is arranged to receive reflected light from an object in accordance with a time sequence in which the at least one light emitter is activated, and accordingly output a plurality of reflected signals. The processing unit is arranged to receive the reflected signals, identify a signal function of time by comparing a predetermined threshold with signal levels of the reflected signals, and determine motion of the object by referring to the signal function of time.

According to another embodiment of the present invention, another exemplary light sensor system is disclosed. The exemplary light sensor system comprises at least one light emitter, a light sensor unit and a processing unit. The light sensor unit is arranged to receive reflected light from an object in accordance with a time sequence in which the at least one light emitter is activated, and accordingly output a plurality of reflected signals. The processing unit is arranged to receive the reflected signals, identify a signal function of time by referring to occurrence sequence of local peak levels of the reflected signals, and determine motion of the object according to the signal function of time.

According to another embodiment of the present invention, another exemplary light sensor system is disclosed. The exemplary light sensor system comprises a panel, a plurality of light emitters, a light sensor unit and a processing unit. The light emitters are correspondingly disposed on a periphery of the panel. The light sensor unit is arranged to receive reflected light from at least one object when the light emitters are activated, and accordingly output a plurality of reflected signals. The processing unit is arranged to receive the reflected signals and determine a position of the at least one object on the panel by referring to local peak levels of the reflected signals.

According to an embodiment of the present invention, an exemplary object detection method is disclosed. The exemplary object detection method comprises: receiving reflected light from an object in accordance with a time sequence in which at least one light emitter is activated, and accordingly outputting a plurality of reflected signals; identifying a signal function of time by comparing a predetermined threshold with signal levels of the reflected signals; and determining motion of the object by referring to the signal function of time.

According to another embodiment of the present invention, another exemplary object detection method is disclosed. The exemplary object detection method comprises: receiving reflected light from an object in accordance with a time sequence in which the light emitter is activated, and accordingly outputting a plurality of reflected signals; identifying a signal function of time by referring to occurrence sequence of local peak levels of the reflected signals; and determining motion of the object according to the signal function of time.

The light sensor system and object detection method of the present invention are capable of detecting and recognizing multiple types of object gestures (e.g. hand gestures), including, but not limited to, tapping (fast moving in the Z-direction); dragging or sliding closer or away from the screen/sensor (in the Z-direction); dragging or sliding from top to bottom (in the Y-direction), from bottom to top (in the Y-direction), from left to right (in the X-direction), from right to left (in the X-direction), in diagonal directions (in the X-direction and Y-direction); and various combinations of the foregoing (i.e., in the X-direction, Y-direction and Z-direction).

The light sensor system and object detection method of the present invention are also capable of recognizing object gestures (e.g. hand gestures) such as drawing a clockwise circle, a counterclockwise circle, combinations of tapping and dragging, combination of tapping and circle(s), dragging and circle(s), and many other combinations. The light sensor system and object detection method are also capable of recognizing that a hand or other object is pointing to a particular location or multiple locations on a screen, in order to facilitate menu selection, selection of map locations, etc.

The light sensor system and object detection method of the present invention can also be used to recognize gestures made by two hands or other objects. For example, two hands separating from the center and moving apart to opposite sides, and coming together from the opposite sides back to the center can be recognized. Such a gesture can be used, for example, to instruct a computer to zoom in or out on a screen.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a generalized light sensor system according to an embodiment of the present invention.

FIG. 2 is a diagram illustrating exemplary configurations of the at least one light emitter and the light sensor unit shown in FIG. 1.

FIG. 3 is a diagram illustrating object detection and gesture recognition in the light sensor system shown in FIG. 1 according to an embodiment of the present invention.

FIG. 4 is a diagram illustrating object detection and gesture recognition in the light sensor system shown in FIG. 1 according to an embodiment of the present invention.

FIG. 5 is a diagram illustrating object detection and gesture recognition in the light sensor system shown in FIG. 1 according to an embodiment of the present invention.

FIG. 6 is a diagram illustrating object detection and gesture recognition in the light sensor system shown in FIG. 1 according to an embodiment of the present invention.

FIG. 7 is a diagram illustrating object detection and gesture recognition in the light sensor system shown in FIG. 1 according to an embodiment of the present invention.

FIG. 8 is a diagram illustrating object detection and gesture recognition in the light sensor system shown in FIG. 1 according to an embodiment of the present invention.

FIG. 9 is a diagram illustrating object detection and gesture recognition in the light sensor system shown in FIG. 1 according to an embodiment of the present invention.

FIG. 10 is a diagram illustrating object detection and gesture recognition in the light sensor system shown in FIG. 1 according to an embodiment of the present invention.

FIG. 11 is a diagram illustrating object detection and gesture recognition in the light sensor system shown in FIG. 1 according to an embodiment of the present invention.

FIG. 12 is a diagram illustrating object detection and gesture recognition in the light sensor system shown in FIG. 1 according to an embodiment of the present invention.

FIG. 13 is a diagram illustrating object detection and gesture recognition in the light sensor system shown in FIG. 1 according to an embodiment of the present invention.

FIG. 14 is a diagram illustrating object detection and gesture recognition in the light sensor system shown in FIG. 1 according to an embodiment of the present invention.

FIG. 15 is a diagram illustrating object detection and gesture recognition in the light sensor system shown in FIG. 1 according to an embodiment of the present invention.

FIG. 16 is a diagram illustrating object detection and gesture recognition in the light sensor system shown in FIG. 1 according to an embodiment of the present invention.

FIG. 17 is a diagram illustrating object detection and gesture recognition in the light sensor system shown in FIG. 1 according to an embodiment of the present invention.

FIG. 18 is a diagram illustrating object detection and gesture recognition in the light sensor system shown in FIG. 1 according to an embodiment of the present invention.

FIG. 19 is a diagram illustrating object detection and gesture recognition in the light sensor system shown in FIG. 1 according to an embodiment of the present invention.

FIG. 20 is a diagram illustrating object detection and gesture recognition in the light sensor system shown in FIG. 1 according to an embodiment of the present invention.

FIG. 21 is a diagram illustrating object detection and gesture recognition in the light sensor system shown in FIG. 1 according to an embodiment of the present invention.

FIG. 22 is a diagram illustrating object detection and gesture recognition in the light sensor system shown in FIG. 1 according to an embodiment of the present invention.

FIG. 23 is a diagram illustrating object detection and gesture recognition in the light sensor system shown in FIG. 1 according to an embodiment of the present invention.

FIG. 24 is a diagram illustrating four straight movements corresponding to a same occurrence sequence of local peak levels in the light sensor system shown in FIG. 1.

FIG. 25 is a diagram illustrating another generalized light sensor system according to an embodiment of the present invention.

FIG. 26 is a diagram illustrating exemplary configurations of light emitter-light sensor pairs and a light emitter-light sensor set over an exemplary screen/panel area represented by numbered blocks according to implementations of the light sensor system shown in FIG. 25.

FIG. 27 is a diagram illustrating exemplary reflectance volumes (or signal levels) of reflected signals corresponding to each of four light emitters in each of the numbered blocks shown in the exemplary configurations of FIG. 26.

FIG. 28 is a diagram illustrating an exemplary light sensor system according to an implementation of the light sensor system shown in FIG. 25.

FIG. 29 is a diagram illustrating another exemplary light sensor system according to another implementation of the light sensor system shown in FIG. 25.

FIG. 30 is a diagram illustrating an exemplary IR emitter-proximity sensor set according to an embodiment of the present invention.

FIG. 31 is a flowchart of an exemplary application used to detect and recognizes hand gestures for the purpose of turning a page in a virtual book displayed on a screen according to an embodiment of the present invention.

FIG. 32 is a diagram illustrating another exemplary light sensor system according to another implementation of the light sensor system shown in FIG. 25.

FIG. 33 is a diagram illustrating hand detection and gesture recognition in the light sensor system shown in FIG. 1 according to an embodiment of the present invention.

FIG. 34 is a diagram illustrating hand detection and gesture recognition shown in FIG. 33 at a later point in time.

FIG. 35 is a diagram illustrating hand detection and gesture recognition in the light sensor system shown in FIG. 1 according to an embodiment of the present invention.

FIG. 36 is a diagram illustrating hand detection and gesture recognition shown in FIG. 35 at a later point in time.

### DETAILED DESCRIPTION

The benefits and advantages of the present invention will become more readily apparent to those of ordinary skill in the relevant art after reviewing the following detailed description and accompanying drawings.

While the objectives of the present invention may be realized in various forms, what is shown in the drawings and will hereinafter be described is a presently preferred embodiment with the understanding that the present disclosure is to be considered an exemplification of the invention and is not intended to limit the invention to the specific embodiment illustrated. It should be further understood that the title of this section of this specification does not imply, nor should be inferred to limit, the subject matter disclosed herein.

The light sensor system and object detection method disclosed in the instant application are related to the inventions disclosed in several earlier patent applications, each of which is assigned to the assignee of the instant application and the present invention, and the content of each of which is incorporated herein by reference, specifically U.S. patent application Ser. Nos. 12/589,360, 13/117,978 and 12/592,109. These prior inventions and patent applications teach the combination of light sensors (proximity sensors with infrared (IR) emitters), and how they are used for proximity touch panel sensing. The present invention and the instant application expand and build upon the identified prior applications and inventions to include object detection and gesture recognition further shown and described herein.

The present invention uses light-reflectance based light sensor(s), or an array of sensors and light emitters, to detect and recognize hand gestures or other object gestures. The light sensor system and object detection method of the present invention preferably include, but are not limited to, at least one light sensor (e.g. a proximity sensor) with at least two (and sometimes three) light emitters (e.g. IR emitters). An array of light sensors and corresponding light emitters can be disposed around a screen/panel or otherwise projected in a space between the screen/panel and the user.

When a user's hand(s) enters the space, this causes a proximity event to be detected that corresponds to particular screen/panel location(s) as defined by the light emitters and the respective light sensor. In addition, this detection also starts a process of recognizing the subsequent proximity events. By recognizing the location and timing sequence of the subsequent events, several hand gestures can be detected and recognized using the light sensor system and object detection method of the present invention.

It will be appreciated that, in the context of the instant application and the present disclosure, an “object gesture” (or a gesture of an object) includes any gesture made to a screen/panel by the object, a hand, multiple objects, multiple hands, any other body part or parts (such as a foot or feet, a head, etc.), gloved or otherwise covered body part or parts, body part or parts holding an object, device, remote control, mouse, or any other object or objects that do not prevent a gesture from being expressed.

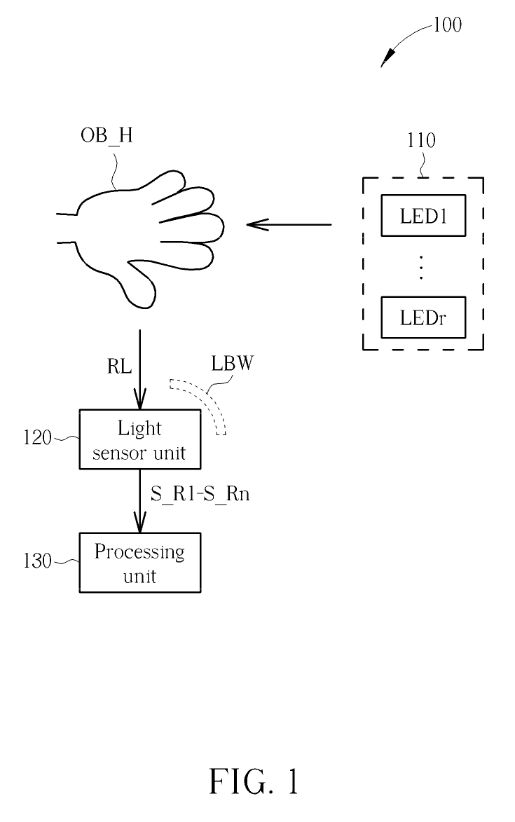

Please refer to FIG. 1, which is a diagram illustrating a generalized light sensor system according to an embodiment of the present invention. The light sensor system 100 includes, but is not limited to, at least one light emitter 110 (e.g. an IR emitter), a light sensor unit 120 (e.g. a proximity sensor unit) and a processing unit 130. The light sensor unit 120 is arranged to receive reflected light RL from an object OB_H (a hand in this embodiment) in accordance with a time sequence t1-tm in which the at least one light emitter 110 is activated, and accordingly output a plurality of reflected signals S_R1-S_Rn. The processing unit 130 is arranged to receive the reflected signals S_R1-S_Rn, identify a signal function of time by referring to occurrence sequence of local peak levels of the reflected signals S_R1-S_Rn, and determine motion of the object OB_H according to the signal function of time. In addition, the processing unit 130 may further recognize a gesture of the object OB_H corresponding to the motion of the object OB_H.

In this embodiment, the light sensor unit 120 may be synchronized with the on-and-off timing of the at least one light emitter 110. Signal levels of the reflected signals S_R1-S_Rn are detected by subtracting an output of the light sensor unit 120 with the at least one light emitter 110 turned off from an output of the light sensor unit 120 with the at least one light emitter 110 turned on. In practice, the at least one light emitter 110 may include a plurality of light emitters LED1-LEDr as shown in FIG. 1, and the processing unit 130 may further control the light emitters LED1-LEDr to be activated alternately, where the time sequence is a sequence of time division frames. In other words, the multiple light emitters LED1-LEDr are lit one at a time, allowing the light sensor unit 120 to distinguish the received signals S_R1-S_Rn by locations of the corresponding light emitters LED1-LEDr. This is for illustrative purposes only, and is not meant to be a limitation of the present invention. In an alternative design, the processing unit 130 may further control the light emitters LED1-LEDr to be simultaneously activated for emitting light beams with different wavelengths.

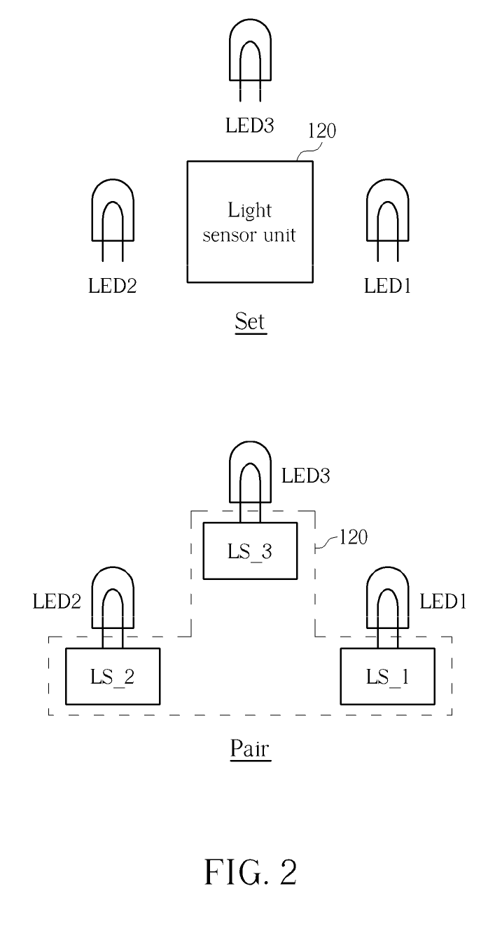

It should be noted that the light sensor unit 120 may include a plurality of light sensors (not shown in FIG. 1), which are dedicated to receiving reflected light corresponding to the light emitters LED1-LEDr, respectively. Please refer to FIG. 2, which is a diagram illustrating exemplary configurations of the at least one light emitter 110 and the light sensor unit 120 shown in FIG. 1. In the top portion of FIG. 2, the light sensor unit 120 with three light emitters LED1-LED3 (included in the at least one light emitter 110) coupled to it may be referred to as a light emitter-light sensor set. In the bottom portion of FIG. 2, each light sensor LS_1-LS_3 (included in the light sensor unit 120) with a single light emitter (the corresponding light emitter LED1-LED3) coupled to it may be referred to as a light emitter-light sensor pair. Multiple light emitter-light sensor sets and/or pairs can be deployed to build an array which increases the capability and spatial resolution of the object gesture recognition of the light sensor system 100.

When multiple light emitter-light sensor sets are used, an external microcontroller unit (MCU), a graphics processing unit (GPU), a base-band processor, a digital signal processor (DSP) and/or a central processing unit (CPU) may be used to synchronize the lighting of the multiple light emitters across several sensors and ensure only one light emitter is lit on at a given time over a given space. Synchronizing the lighting of the multiple light emitters in this manner by using such control devices is known by those skilled in the art. In one embodiment, the multiple light emitters may be allowed to be lit simultaneously over non-overlapping projected spaces. In another embodiment, when the multiple light emitters are lit over the same projected space, different wavelengths may be used and the corresponding light sensor(s) may include filters, such as narrow band IR spectrum filters, which allow only the wavelengths of the correct light emitters emitting IR light beams to be detected.

Those skilled in the art should also recognize that various types of light emitters may be used with the light sensor system and object detection method of the present invention, without departing from the scope of the instant disclosure. For example, depending on the light emitter used, the emitted light signal can be a pulse, or a series of modulated pulses (pulse modulation).

As mentioned above, the processing unit 130 is configured to receive the reflected signals S_R1-S_Rn, identify the signal function of time by referring to the occurrence sequence of the local peak levels of the reflected signals S_R1-S_Rn, and determine the motion of the object OB_H according to the signal function of time. In practice, the light sensor unit 120 may be configured to receive the reflected IR signal, process signals through an analog-to-digital converter (ADC), filter the signals, and demodulate the signals in the case of light-energy based light sensors, or detect the phase or timing of the signals in the case of time-based light sensors such as time-of-flight (TOF)-type proximity sensors. All such light emitters and light sensors, and combinations thereof, fall within the scope of the instant disclosure.

Additionally, as those skilled in the art will appreciate, a signal level (a reflectance volume) of a reflected signal shown in the figures of the instant application represents what a light sensor unit measures that is related to the X, Y and Z distances of the object(s) (e.g., hand(s)) to the light sensor unit. In the examples displayed in the figures, as the distance between the light sensor unit and the object(s) (e.g., hand(s)) decreases, the signal level increases, and vice versa. However, in other embodiments of the present invention, as the distance between the light sensor unit and the object(s) (e.g., hand(s)) decreases, the signal level may decrease, and vice versa. Thus, the relationship between the distance and the signal level may be directly proportional, or may be inversely proportional (although not necessarily linear). All such variations in the relationship between the distance and the signal level are included within the scope of the present disclosure.

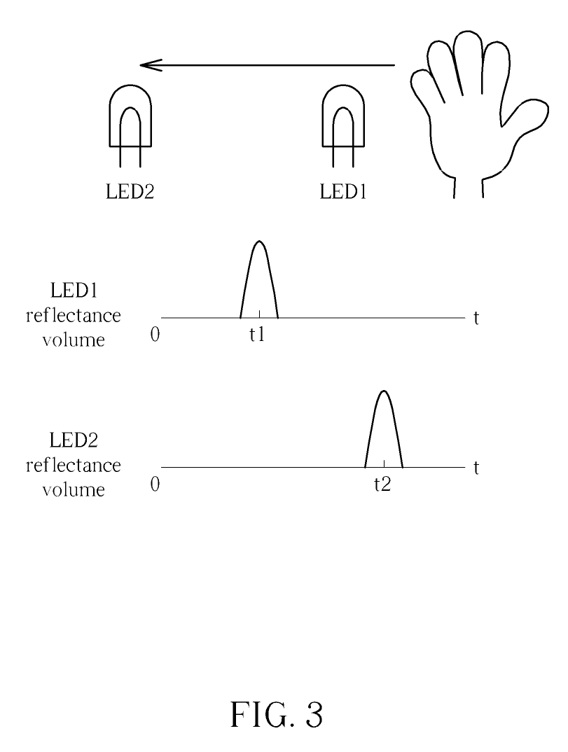

As discussed in detail below, FIGS. 3-24 illustrate numerous object gestures (e.g., hand gestures) detected and recognized using the light sensor system and object detection method of the present invention by detecting the change of the hand in X-Y-Z locations over time. Examples of detection and recognition of certain object gestures (e.g. hand gestures) are provided below; however, those skilled in the art will recognize that it is possible to detect and recognize a wide variety of object gestures (e.g. hand gestures) using the light sensor system and object detection method of the present invention, and all such object gestures (e.g. hand gestures) and detection/recognition methods thereof also fall within the scope of the instant disclosure.

Moreover, those skilled in the art will recognize that there are various combinations of light emitters and light sensors, including variations of the numbers and locations of such light emitters and light sensors relative to a screen/panel, which are possible in the light sensor system and object detection method of the present invention. All such combinations, number and locations of such light emitters and light sensors are included within the scope of the instant disclosure.

It will be further appreciated by those skilled in the art that references in the instant application and drawings to an “LED” means a light emitter, whether it is a light emitting diode (LED), a laser LED, or a scanning mirror or any other means of illumination. Moreover, IR in the context of the present invention means infrared light with wavelength preferably above 700 nm but below 1.3 μm. Other wavelengths, such as those between 300 nm and 700 nm in the visible spectrum, are included within the scope of the instant disclosure.

Please refer to FIG. 3, which is a diagram illustrating object detection and gesture recognition in the light sensor system 100 shown in FIG. 1 according to an embodiment of the present invention. As shown in FIG. 3, two light emitters LED1 and LED2 may be used with one light sensor or two light sensors (not shown in FIG. 3) as a light emitter-light sensor set or two light emitter-light sensor pairs described in paragraphs directed to the FIG. 2 to detect and recognize an object (a hand in this embodiment) moving from right to left. The light emitters LED1 and LED2 may be lit one at a time, and reflectance volumes (signal levels of the reflected signals S_R1-S_Rn) represent what the light sensor unit 120 (not shown in FIG. 3) detects corresponding to each of the light emitters LED1 and LED2. In this embodiment, the reflected signals S_R1-S_Rn generated from the light sensor unit 120 include a plurality of first reflected signals S_R11-S_R1n corresponding to the light emitter LED1 and a plurality of second reflected signals S_R21-S_R2n corresponding to the second light emitter LED2. In addition, the processing unit 130 (not shown in FIG. 3) identifies the signal function of time by referring to occurrence sequence of local peak levels of the first reflected signals S_R11-S_R1n and the second reflected signals S_R21-S_R2n, and determines the motion of the hand by referring to the identified signal function of time.

As shown in FIG. 3, a local peak level of the first reflected signals S_R11-S_R1n occurs at time t1, and a local peak level of the second reflected signals S_R21-S_R2n occurs at time t2 after time t1. The identified signal function of time indicates that the local peak level of the first reflected signals S_R11-S_R1n occurs before the local peak level of the second reflected signals S_R21-S_R2n, and thus the processing unit 130 determines that the hand is moving from the light emitter LED1 toward the light emitter LED2. In brief, movement to the left (from the light emitter LED1 to the light emitter LED2) is recognized by referring to the identified signal function of time, which indicates the occurrence sequence of local peak levels of the light emitters LED1 and LED2 in the time sequence.

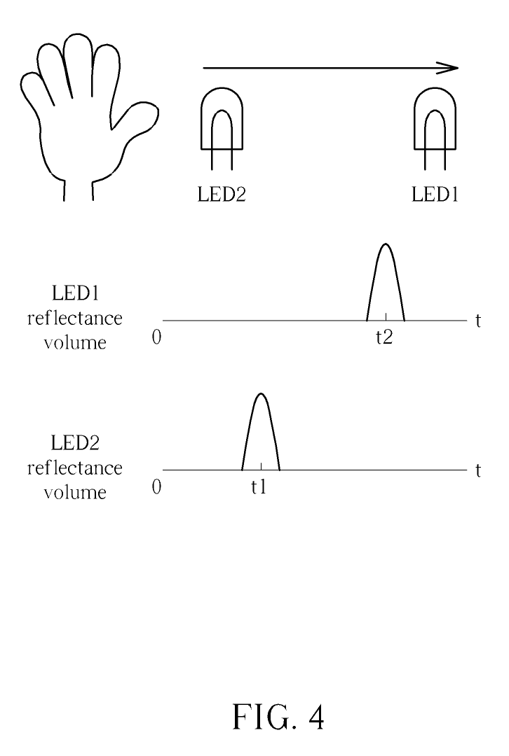

Please refer to FIG. 4, which is a diagram illustrating object detection and gesture recognition in the light sensor system 100 shown in FIG. 1 according to an embodiment of the present invention. As shown in FIG. 4, two light emitters LED1 and LED2 may be used with one light sensor or two light sensors (not shown in FIG. 4) to detect and recognize an object (a hand in this embodiment) moving from left to right. The light emitters LED1 and LED2 may be lit one at a time, and reflectance volumes (signal levels of the reflected signals S_R1-S_Rn) represent what the light sensor unit 120 (not shown in FIG. 4) detects corresponding to each of the light emitters LED1 and LED2. Similarly, in this embodiment, the reflected signals S_R1-S_Rn generated from the light sensor unit 120 include a plurality of first reflected signals S_R11-S_R1n corresponding to the light emitter LED1 and a plurality of second reflected signals S_R21-S_R2n corresponding to the second light emitter LED2. In addition, the processing unit 130 (not shown in FIG. 4) identifies the signal function of time by referring to occurrence sequence of local peak levels of the first reflected signals S_R11-S_R1n and the second reflected signals S_R21-S_R2n, and determines the motion of the hand by referring to the identified signal function of time.

As shown in FIG. 4, a local peak level of the second reflected signals S_R21-S_R2n occurs at time t1, and a local peak level of the first reflected signals S_R11-S_R1n occurs at time t2 after time t1. The identified signal function of time indicates that the local peak level of the second reflected signals S_R21-S_R2n occurs before the local peak level of the first reflected signals S_R11-S_R1n, and thus the processing unit 130 determines that the hand is moving from the light emitter LED2 toward the light emitter LED1. In brief, movement to the right is recognized by referring to the identified signal function of time, which indicates the occurrence sequence of local peak levels of the light emitters LED1 and LED2 in the time sequence.

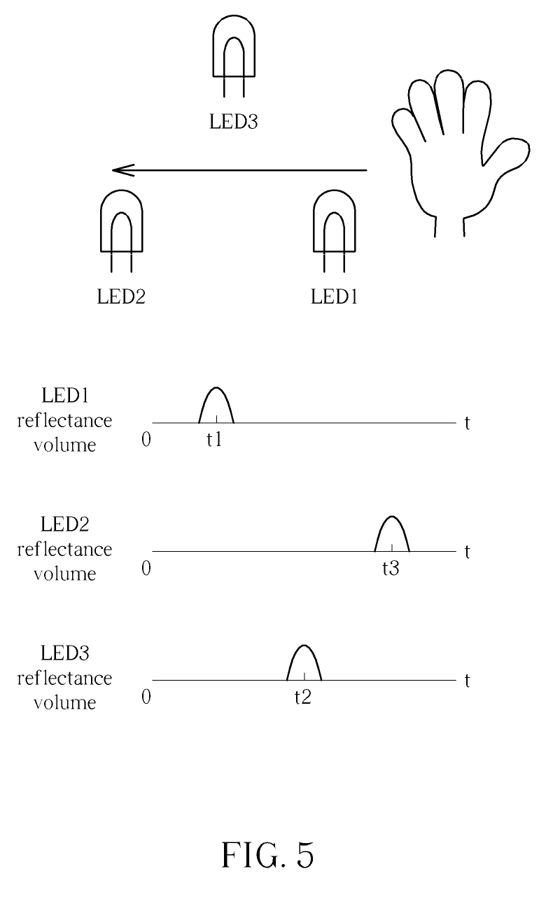

Please refer to FIG. 5, which is a diagram illustrating object detection and gesture recognition in the light sensor system 100 shown in FIG. 1 according to an embodiment of the present invention. As shown in FIG. 5, a hand is detected and recognized to move from right to left by using a light emitter-light sensor set (LED1, LED2, LED 3 and the light sensor unit 120 (not shown in FIG. 5)). Each light emitter is lit one at a time, and reflectance volumes (signal levels of the reflected signals S_R1-S_Rn) are collected as the signal function of time, corresponding to each light emitter being lit. In this embodiment, the reflected signals S_R1-S_Rn generated from the light sensor unit 120 include a plurality of first reflected signals S_R11-S_R1n corresponding to the light emitter LED1, a plurality of second reflected signals S_R21-S_R2n corresponding to the light emitter LED2 and a plurality of third reflected signals S_R31-S_R3n corresponding to the light emitter LED3. In addition, the processing unit 130 (not shown in FIG. 5) identifies the signal function of time by referring to occurrence sequence of local peak levels of the first reflected signals S_R11-S_R1n, the second reflected signals S_R21-S_R2n and the third reflected signals S_R31-S_R3n, and determines the motion of the hand by referring to the identified signal function of time.

As shown in FIG. 5, a local peak level of the first reflected signals S_R11-S_R1n occurs at time t1, a local peak level of the third reflected signals S_R31-S_R3n occurs at time t2 after time t1, and a local peak level of the second reflected signals S_R21-S_R2n occurs at time t3 after time t2. The identified signal function of time indicates that local peak levels of the first reflected signals S_R11-S_R1n, the second reflected signals S_R21-S_R2n and the third reflected signals S_R31-S_R3n occur in sequence in the time sequence, and thus the processing unit 130 determines that the hand is moving from the emitter LED1 toward the light emitter LED2 through the light emitter LED3. In one implementation, the processing unit 130 may perform subsequent digital signal processing to recognize the hand gesture by referring to occurrence sequence of local peak levels in the time sequence.

It will be appreciated by those skilled in the art that the use of three light emitters LED1-LED3 in the illustrated light emitter-light sensor set is not meant to be a limitation. A light emitter-light sensor set with more than three light emitters can be used and deployed around a screen/panel, a computer, mobile device, etc. without departing from the scope of the instant disclosure, as long as the ability is maintained to measure the reflected signals as a function of time corresponding to each light emitter being lit.

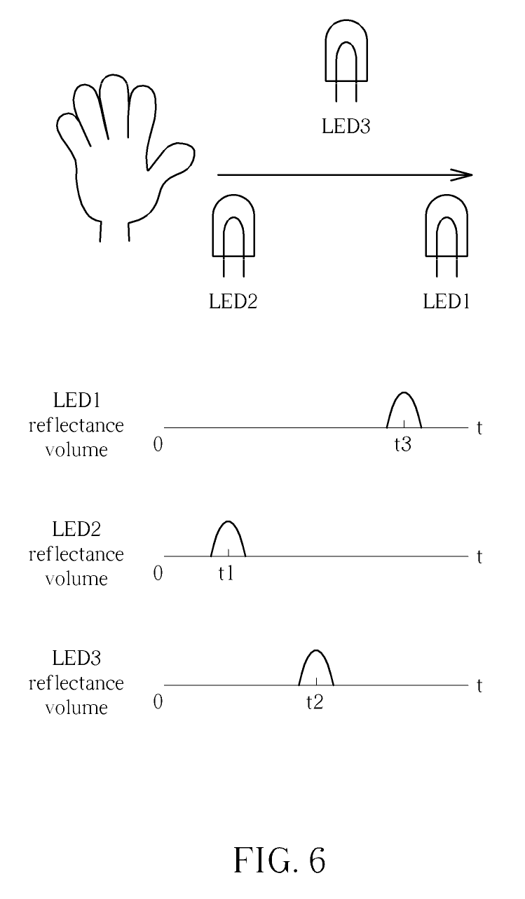

Please refer to FIG. 6, which is a diagram illustrating object detection and gesture recognition in the light sensor system 100 shown in FIG. 1 according to an embodiment of the present invention. As shown in FIG. 6, a hand is detected and recognized to move from left to right by using a light emitter-light sensor set (LED1, LED2, LED 3 and the light sensor unit 120 (not shown in FIG. 6)). Each light emitter is lit one at a time, and reflectance volumes (signal levels of the reflected signals S_R1-S_Rn) are collected as the signal function of time, corresponding to each light emitter being lit. In one implementation, the processing unit 130 may perform subsequent digital signal processing to recognize the hand gesture by referring to occurrence sequence of local peak levels in the time sequence.

It will be appreciated by those skilled in the art that two or more light emitters coupled or paired to a single light sensor can be a light emitter-light sensor set. In addition, multiple light emitter-light sensor pairs, multiple light emitter-light sensor sets, and/or combinations of light emitter-light sensor pairs and light emitter-light sensor sets can be used to detect and recognize object gestures (e.g., hand gestures) within the scope of the present invention, and each of the illustrated object gestures (e.g. hand gestures) discussed in the instant applicant can be detected and recognized using such pair(s), set(s) and/or combination(s) thereof. The layout and density of the pair(s), set(s) and/or combination(s) controls the level of resolution/performance.

In one embodiment, for each light emitter-light sensor pair or set, the light emitter(s) preferably should be located within a close distance to the light sensor unit. The maximum distance between the light emitter(s) and light sensor unit is determined by the desired resolution of the object gesture (e.g. hand gesture) and screen/panel pointing, the emitting angle of the light emitter(s), the space or area where the object gestures (e.g. hand gestures) are intended to be detected, the viewing angle of the light sensor, the emitting power of the light emitter(s) and the typical light reflectance of the object that generates the object gesture (e.g. hand gesture).

Please refer to FIG. 2 again. The light emitter-light sensor set shown in the top configuration of FIG. 2 may use a light-guide, light-pipe or equivalent devices to help transmit the light from to light emitters LED1-LED3 to the light sensor unit 120. The use of a light guide, light pipe or similar device allows the same light sensor to light emitter ratio, but with improved spatial signal to noise performance.

Additionally, as will be appreciated by those skilled in the art, in designing the layout of the light sensors and the light emitters, it is important to minimize the crosstalk between light emitters and light sensors (a direct leakage of the light from light emitters to the light sensors). By way of example, the light sensor system 100 shown in FIG. 1 may further include a light barrier wall LBW formed between the at least one light emitter 110 and the light sensor unit 120, wherein the light barrier wall LBW is arranged to interrupt traveling of stray light emitted from the at least one light emitter 110. Also, a narrow light emitter emitting angle will help to minimize the emitted light going astray, and a narrow light sensor viewing angle (typically through packaging or optical module design) will also help in reducing received crosstalk.

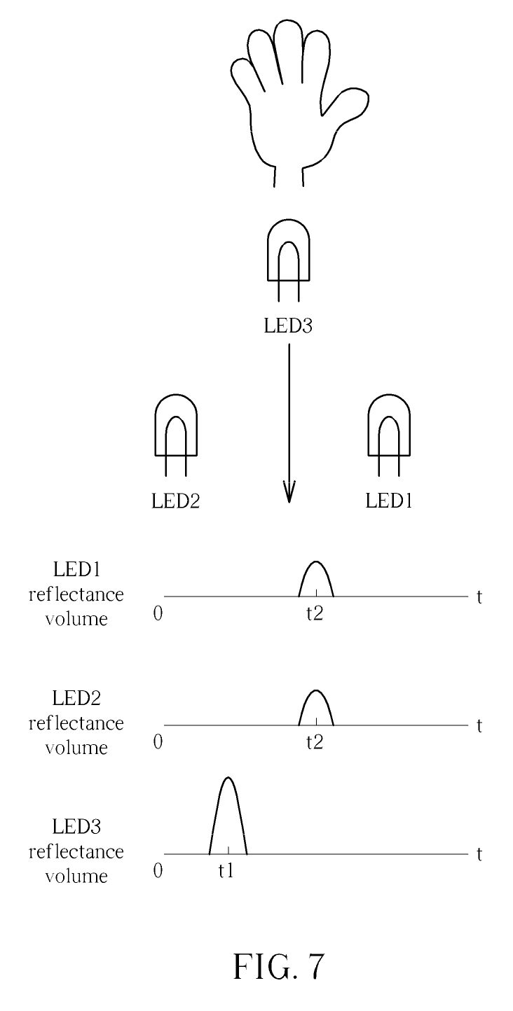

Please refer to FIG. 7, which is a diagram illustrating object detection and gesture recognition in the light sensor system 100 shown in FIG. 1 according to an embodiment of the present invention. As shown in FIG. 7, a hand is detected and recognized to move down by using a light emitter-light sensor set (LED1, LED2, LED 3 and the light sensor unit 120 (not shown in FIG. 7)). Each light emitter is lit one at a time, and reflectance volumes (signal levels of the reflected signals S_R1-S_Rn) are collected as the signal function of time, corresponding to each light emitter being lit. In this embodiment, the reflected signals S_R1-S_Rn generated from the light sensor unit 120 include a plurality of first reflected signals S_R11-S_R1n corresponding to the light emitter LED1, a plurality of second reflected signals S_R21-S_R2n corresponding to the light emitter LED2 and a plurality of third reflected signals S_R31-S_R3n corresponding to the light emitter LED3. In addition, the processing unit 130 (not shown in FIG. 7) identifies the signal function of time by referring to occurrence sequence of local peak levels of the first reflected signals S_R11-S_R1n, the second reflected signals S_R21-S_R2n and the third reflected signals S_R31-S_R3n, and determines the motion of the hand by referring to the identified signal function of time.

As shown in FIG. 7, the identified signal function of time indicates that local peak levels of the first reflected signals S_R11-S_R1n and the second reflected signals S_R21-S_R2n occur substantially at the same time (time t2) immediately after occurrence of a local peak level of the third reflected signals S_R31-S_R3n (time t1), and thus the processing unit 130 determines that the hand is moving from the light emitter LED3 toward a position between the light emitters LED1 and LED2. In one implementation, the processing unit 130 may perform subsequent digital signal processing to recognize the hand gesture by referring to occurrence sequence of local peak levels in the time sequence. Please note that, in the embodiments of the light sensor system and object detection method of the present invention discussed and disclosed throughout the instant application, the DSP calculation/processing may be integrated with the light sensor in one chip, in one module, or not integrated with the light sensor by running the program (driver code) by the host microprocessors. Those skilled in the art will appreciate that all such variations are included within the scope of the instant disclosure.

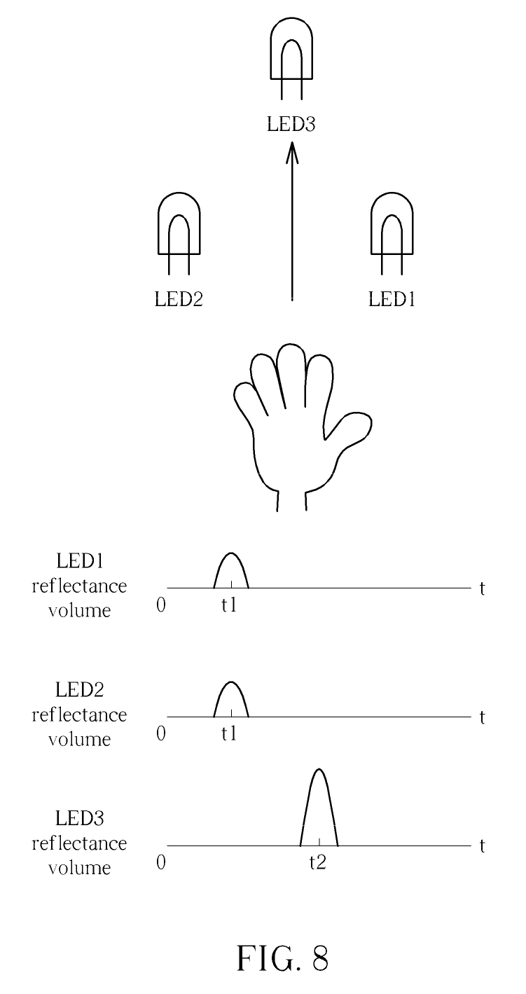

Please refer to FIG. 8, which is a diagram illustrating object detection and gesture recognition in the light sensor system 100 shown in FIG. 1 according to an embodiment of the present invention. As shown in FIG. 8, a hand is detected and recognized to move up by using a light emitter-light sensor set (LED1, LED2, LED 3 and the light sensor unit 120 (not shown in FIG. 8)). Each light emitter is lit one at a time, and reflectance volumes (signal levels of the reflected signals S_R1-S_Rn) are collected as the signal function of time, corresponding to each light emitter being lit. In this embodiment, the reflected signals S_R1-S_Rn generated from the light sensor unit 120 include a plurality of first reflected signals S_R11-S_R1n corresponding to the light emitter LED1, a plurality of second reflected signals S_R21-S_R2n corresponding to the light emitter LED2 and a plurality of third reflected signals S_R31-S_R3n corresponding to the light emitter LED3. In addition, the processing unit 130 (not shown in FIG. 8) identifies the signal function of time by referring to occurrence sequence of local peak levels of the first reflected signals S_R11-S_R1n, the second reflected signals S_R21-S_R2n and the third reflected signals S_R31-S_R3n, and determines the motion of the hand by referring to the identified signal function of time.

As shown in FIG. 8, the identified signal function of time indicates that local peak levels of the first reflected signals S_R11-S_R1n and the second reflected signals S_R21-S_R2n occur substantially at the same time (time t1) immediately before occurrence of a local peak level of the third reflected signals S_R31-S_R3n (time t2), and thus the processing unit 130 determines that the hand is moving from a position between the light emitters LED1 and LED2 toward the light emitter LED3. In one implementation, the processing unit 130 may perform subsequent digital signal processing to recognize the hand gesture by referring to occurrence sequence of local peak levels in the time sequence.

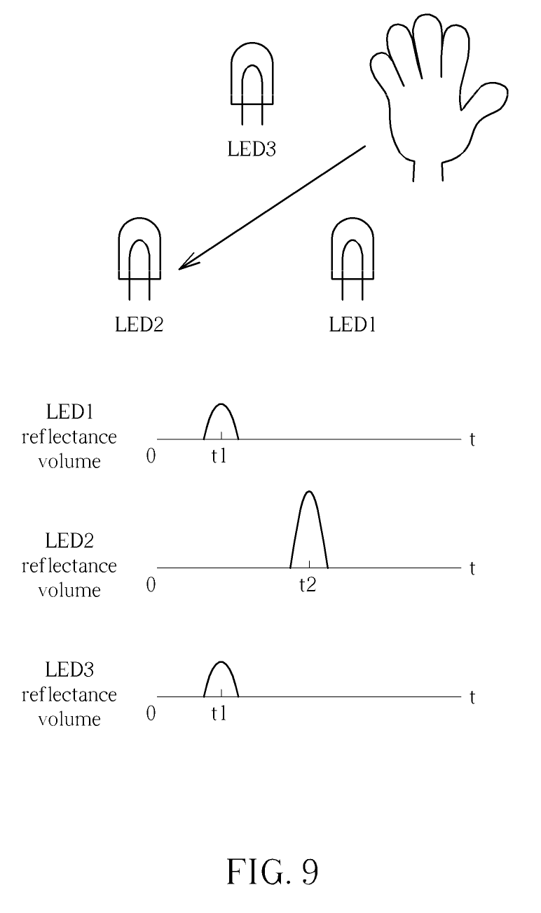

Please refer to FIG. 9, which is a diagram illustrating object detection and gesture recognition in the light sensor system 100 shown in FIG. 1 according to an embodiment of the present invention. As shown in FIG. 9, a hand is detected and recognized to move diagonally from top right to bottom left by using a light emitter-light sensor set (LED1, LED2, LED 3 and the light sensor unit 120 (not shown in FIG. 9)). Each light emitter is lit one at a time, and reflectance volumes (signal levels of the reflected signals S_R1-S_Rn) are collected as the signal function of time, corresponding to each light emitter being lit. It should be noted that the identified signal function of time shown in FIG. 9 is similar to that shown in FIG. 8. More particularly, in this embodiment, the identified signal function of time indicates that local peak levels of the first reflected signals S_R11-S_R1n and the third reflected signals S_R31-S_R3n occur substantially at the same time (time t1) immediately before occurrence of a local peak level of the second reflected signals S_R21-S_R2n (time t2), and thus the processing unit 130 determines that the hand is moving from a position between the light emitters LED1 and LED3 toward the light emitter LED2. In one implementation, the processing unit 130 may perform subsequent digital signal processing to recognize the hand gesture by referring to occurrence sequence of local peak levels in the time sequence.

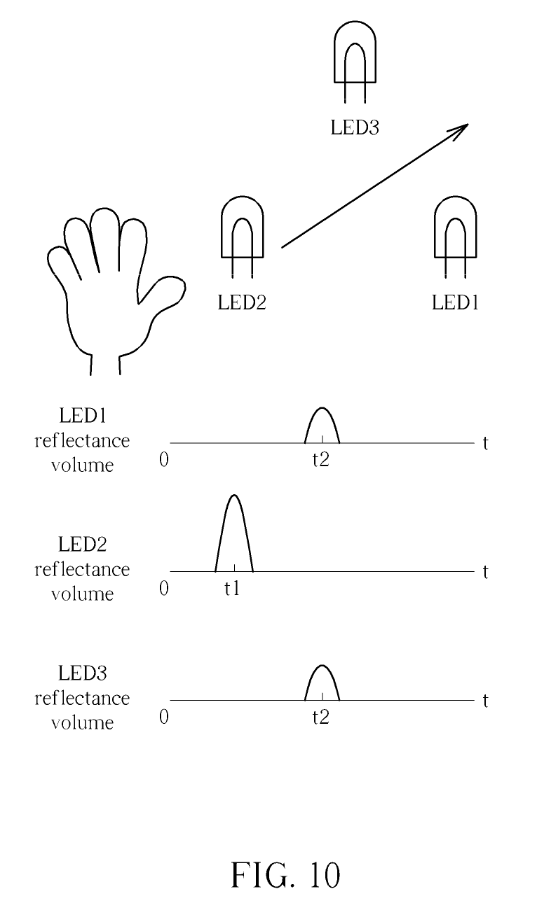

Please refer to FIG. 10, which is a diagram illustrating object detection and gesture recognition in the light sensor system 100 shown in FIG. 1 according to an embodiment of the present invention. As shown in FIG. 10, a hand is detected and recognized to move diagonally from bottom left to top right by using a light emitter-light sensor set (LED1, LED2, LED 3 and the light sensor unit 120 (not shown in FIG. 10)). Each light emitter is lit one at a time, and reflectance volumes (signal levels of the reflected signals S_R1-S_Rn) are collected as the signal function of time, corresponding to each light emitter being lit. It should be noted that the identified signal function of time shown in FIG. 10 is similar to that shown in FIG. 7. More particularly, in this embodiment, the identified signal function of time indicates that local peak levels of the first reflected signals S_R11-S_R1n and the third reflected signals S_R31-S_R3n occur substantially at the same time (time t2) immediately after occurrence of a local peak level of the second reflected signals S_R21-S_R2n (time t1), and thus the processing unit 130 determines that the hand is moving from the light emitter LED2 toward a position between the light emitters LED1 and LED3. In one implementation, the processing unit 130 may perform subsequent digital signal processing to recognize the hand gesture by referring to occurrence sequence of local peak levels in the time sequence.

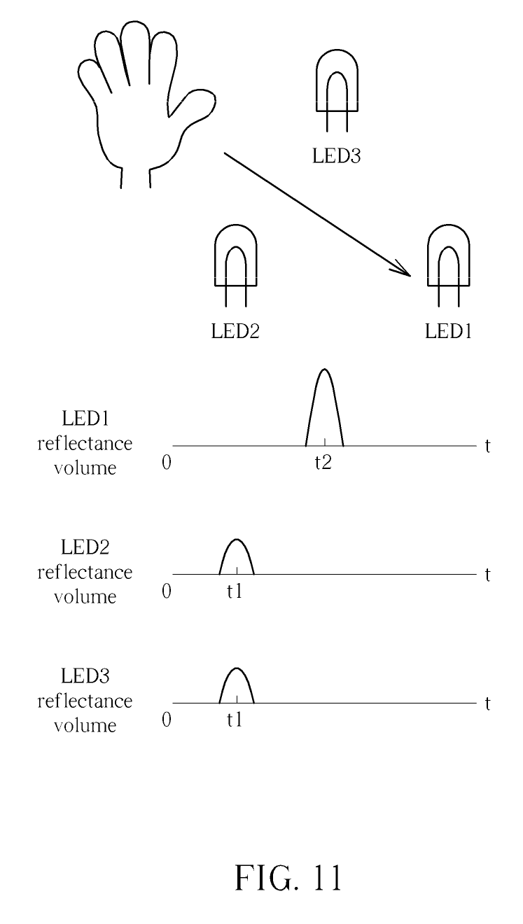

Please refer to FIG. 11, which is a diagram illustrating object detection and gesture recognition in the light sensor system 100 shown in FIG. 1 according to an embodiment of the present invention. As shown in FIG. 11, a hand is detected and recognized to move diagonally from top left to bottom right by using a light emitter-light sensor set (LED1, LED2, LED 3 and the light sensor unit 120 (not shown in FIG. 11)). Each light emitter is lit one at a time, and reflectance volumes (signal levels of the reflected signals S_R1-S_Rn) are collected as the signal function of time, corresponding to each light emitter being lit. It should be noted that the identified signal function of time shown in FIG. 11 is similar to that shown in FIG. 8. More particularly, in this embodiment, the identified signal function of time indicates that local peak levels of the second reflected signals S_R21-S_R2n and the third reflected signals S_R31-S_R3n occur substantially at the same time (time t1) immediately before occurrence of a local peak level of the first reflected signals S_R11-S_R1n (time t2), and thus the processing unit 130 determines that the hand is moving from a position between the light emitters LED2 and LED3 toward the light emitter LED1. In one implementation, the processing unit 130 may perform subsequent digital signal processing to recognize the hand gesture by referring to occurrence sequence of local peak levels in the time sequence.

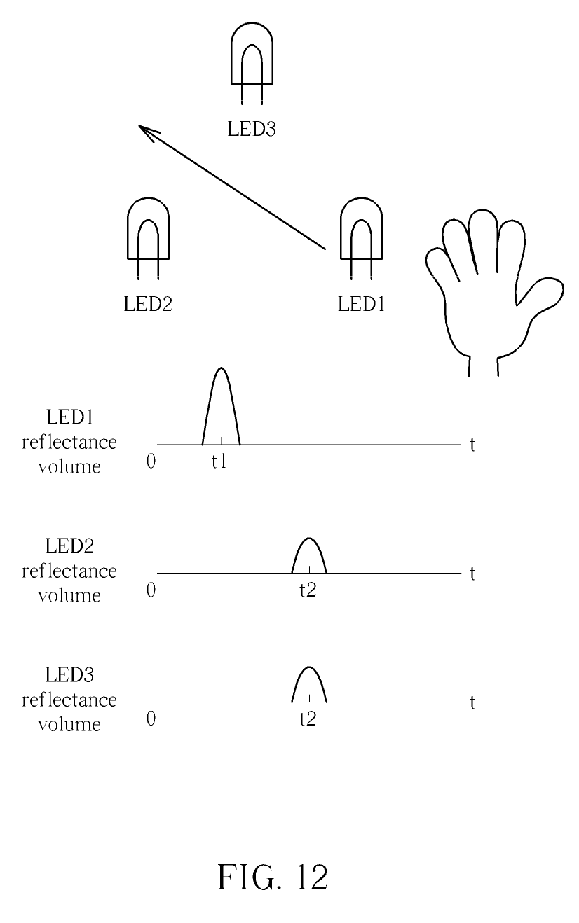

Please refer to FIG. 12, which is a diagram illustrating object detection and gesture recognition in the light sensor system 100 shown in FIG. 1 according to an embodiment of the present invention. As shown in FIG. 12, a hand is detected and recognized to move diagonally from bottom right to top left by using a light emitter-light sensor set (LED1, LED2, LED 3 and the light sensor unit 120 (not shown in FIG. 12)). Each light emitter is lit one at a time, and reflectance volumes (signal levels of the reflected signals S_R1-S_Rn) are collected as the signal function of time, corresponding to each light emitter being lit. It should be noted that the identified signal function of time shown in FIG. 12 is similar to that shown in FIG. 7. More particularly, in this embodiment, the identified signal function of time indicates that local peak levels of the second reflected signals S_R21-S_R2n and the third reflected signals S_R31-S_R3n occur substantially at the same time (time t2) immediately after occurrence of a local peak level of the first reflected signals S_R11-S_R1n (time t1), and thus the processing unit 130 determines that the hand is moving from the light emitter LED1 toward a position between the light emitters LED2 and LED3. In one implementation, the processing unit 130 may perform subsequent digital signal processing to recognize the hand gesture by referring to occurrence sequence of local peak levels in the time sequence.

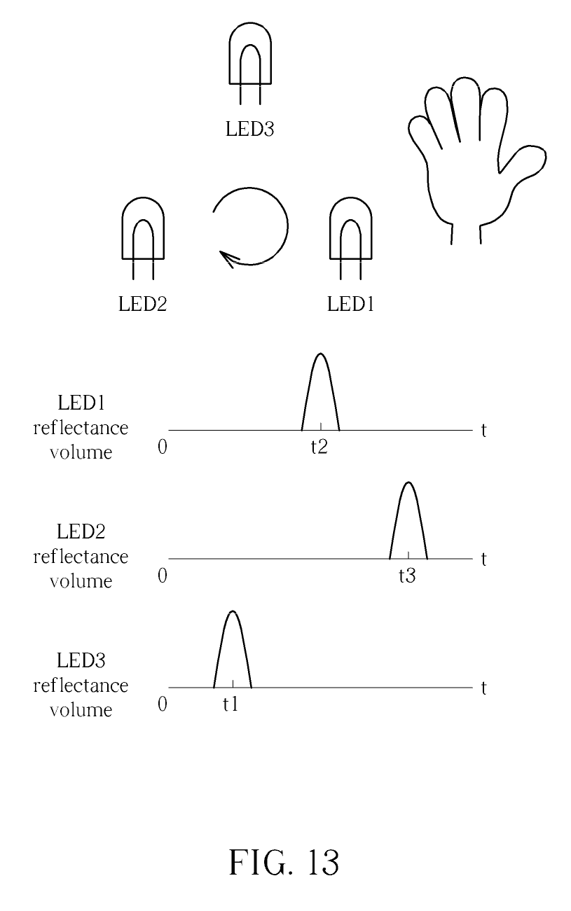

Please refer to FIG. 13, which is a diagram illustrating object detection and gesture recognition in the light sensor system 100 shown in FIG. 1 according to an embodiment of the present invention. As shown in FIG. 13, a hand is detected and recognized to move in a clockwise circular direction by using a light emitter-light sensor set (LED1, LED2, LED 3 and the light sensor unit 120 (not shown in FIG. 13)). Each light emitter is lit one at a time, and reflectance volumes (signal levels of the reflected signals S_R1-S_Rn) are collected as the signal function of time, corresponding to each light emitter being lit. It should be noted that the identified signal function of time shown in FIG. 13 is similar to that shown in FIG. 6. In other words, the occurrence sequence of the local peak levels shown in FIG. 6 may be regarded as a clockwise movement. The major difference between the identified signal functions of time shown in FIG. 6 and FIG. 13 is reflectance volumes (signal levels) of the local peak levels. More particularly, due to the distance between the light emitter and the hand, the local peak levels corresponding to a straight movement (from the light emitter LED2 toward and the light emitter LED1 through the light emitter LED3) are substantially less than the local peak levels corresponding to a circular movement (from the light emitter LED2 toward and the light emitter LED1 through the light emitter LED3). Therefore, in this embodiment, the processing unit 130 shown in FIG. 1 may further compare a predetermined level with the local peak levels of the first reflected signals S_R11-S_R1n, the third reflected signals S_R31-S_R3n and the second reflected signals S_R21-S_R2n, and determine that the hand has a circular movement when each of the local peak levels of the first reflected signals S_R11-S_R1n, the third reflected signals S_R31-S_R3n and the second reflected signals S_R21-S_R2n is higher than the predetermined level. In one implementation, the processing unit 130 may perform subsequent digital signal processing to recognize the hand gesture by referring to occurrence sequence of local peak levels in the time sequence.

In the embodiment described in FIG. 6, the processing unit 130 shown in FIG. 1 may further compare a predetermined level with the local peak levels of the first reflected signals S_R11-S_R1n, the third reflected signals S_R31-S_R3n and the second reflected signals S_R21-S_R2n, and determines that the hand has a straight movement when at least one of the local peak levels of the first reflected signals S_R11-S_R1n, the third reflected signals S_R31-S_R3n and the second reflected signals S_R21-S_R2n is lower than the predetermined level.

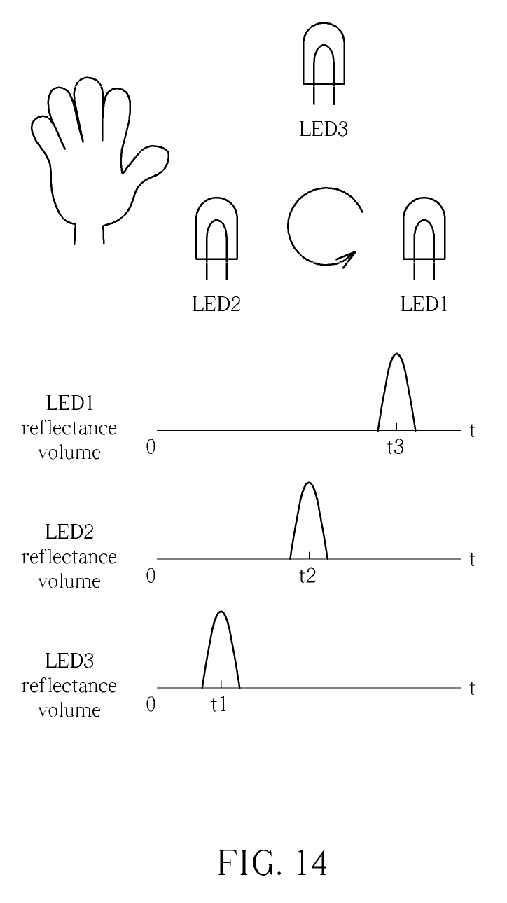

Please refer to FIG. 14, which is a diagram illustrating object detection and gesture recognition in the light sensor system 100 shown in FIG. 1 according to an embodiment of the present invention. As shown in FIG. 6, a hand is detected and recognized to move in a counter-clockwise circular direction by using a light emitter-light sensor set (LED1, LED2, LED 3 and the light sensor unit 120 (not shown in FIG. 6)). Each light emitter is lit one at a time, and reflectance volumes (signal levels of the reflected signals S_R1-S_Rn) are collected as the signal function of time, corresponding to each light emitter being lit. Similarly, the identified signal function of time shown in FIG. 14 is similar to that shown in FIG. 5, and the major difference between the identified signal functions of time shown in FIG. 5 and FIG. 14 is reflectance volumes (signal levels) of the local peak levels. Therefore, in this embodiment, the processing unit 130 shown in FIG. 1 may further compare a predetermined level with the local peak levels of the first reflected signals S_R11-S_R1n, the third reflected signals S_R31-S_R3n and the second reflected signals S_R21-S_R2n, and determine that the hand has a circular movement when each of the local peak levels of the first reflected signals S_R11-S_R1n, the third reflected signals S_R31-S_R3n and the second reflected signals S_R21-S_R2n is higher than the predetermined level. In one implementation, the processing unit 130 may perform subsequent digital signal processing to recognize the hand gesture by referring to occurrence sequence of local peak levels in the time sequence.

In the embodiment described in FIG. 5, the processing unit 130 shown in FIG. 1 may further compare a predetermined level with the local peak levels of the first reflected signals S_R11-S_R1n, the third reflected signals S_R31-S_R3n and the second reflected signals S_R21-S_R2n, and determine that the hand has a straight movement when at least one of the local peak levels of the first reflected signals S_R11-S_R1n, the third reflected signals S_R31-S_R3n and the second reflected signals S_R21-S_R2n is lower than the predetermined level.

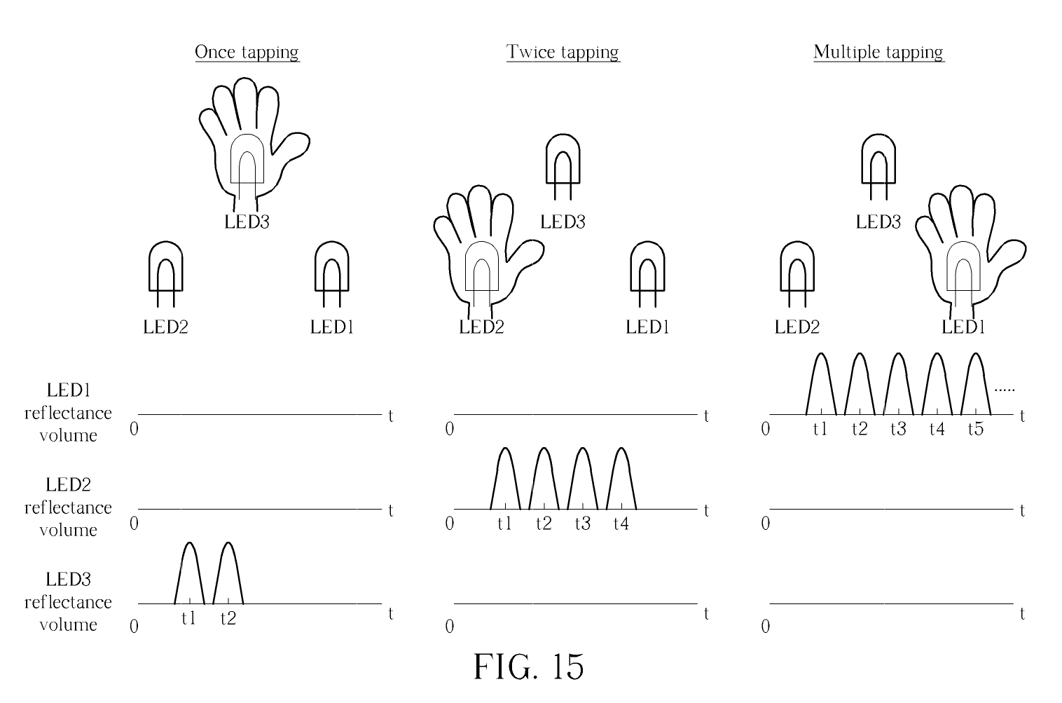

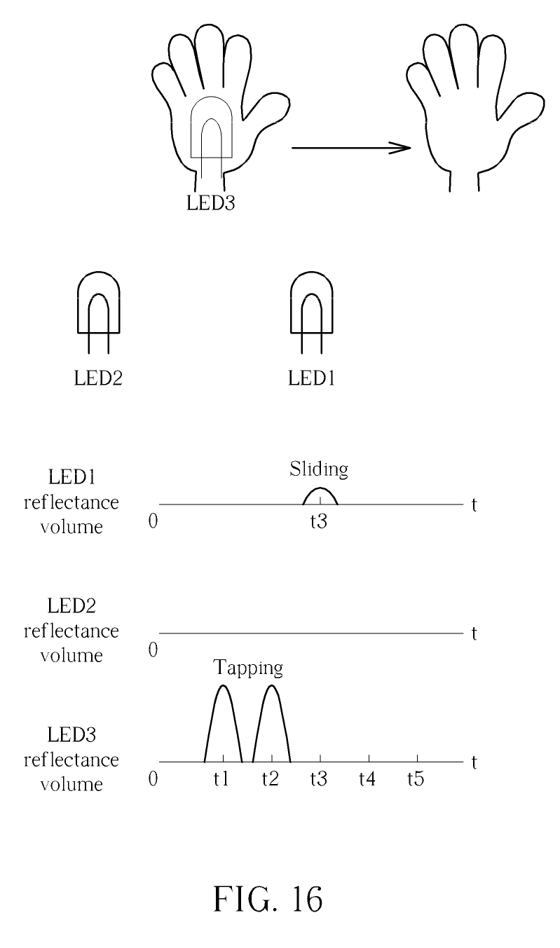

Please refer to FIG. 15, which is a diagram illustrating object detection and gesture recognition in the light sensor system 100 shown in FIG. 1 according to an embodiment of the present invention. As shown in FIG. 15, a hand tapping (moving in Z-direction) is detected, wherein the hand tapping is analogous to tapping the screen/panel once in one location (i.e. leftmost portion of FIG. 15), twice in another location (i.e. middle portion of FIG. 15), or three or more times (i.e. rightmost portion of FIG. 15). More particularly, when the identified signal function indicates that the local peak levels of the reflected signals S_R1-S_Rn of the light system 100 shown in FIG. 1 have substantially the same magnitude and occur sequentially, the processing unit 130 determines that the object (e.g., the hand) is moving to and fro with respect to the at least one light emitter 110 (at least one of the light emitters LED1-LED3). In addition, the processing unit 130 may further refer to the number of local peak levels to determine the number of times the object (e.g. the hand) is moving to and fro with respect to the at least one light emitter 110 (e.g. at least one of the light emitters LED1-LED3). In brief, the light sensor system and object detection method of the present invention are capable of detecting both the location of the tapping on the screen/panel, the number of the tapping at that location, and the sequence of the tapping at various locations (and the sequence of other hand gestures in combination with tapping as shown in FIGS. 16-23).

Please refer to FIG. 16, which is a diagram illustrating object detection and gesture recognition in the light sensor system 100 shown in FIG. 1 according to an embodiment of the present invention. As shown in FIG. 16, a hand tapping and sliding from left to right is detected and recognized by using a light emitter-light sensor set (LED1, LED2, LED 3 and the light sensor unit 120 (not shown in FIG. 16)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitter (the light emitter LED3). The sliding is recognized by the diminished signal strength over time associated with the origination light emitter location (the location corresponding to the light emitter LED3). In other words, the sliding is recognized by referring to the identified signal function of time indicating the occurrence sequence of the local peak levels of the light emitter LED3 and the light emitter LED1.

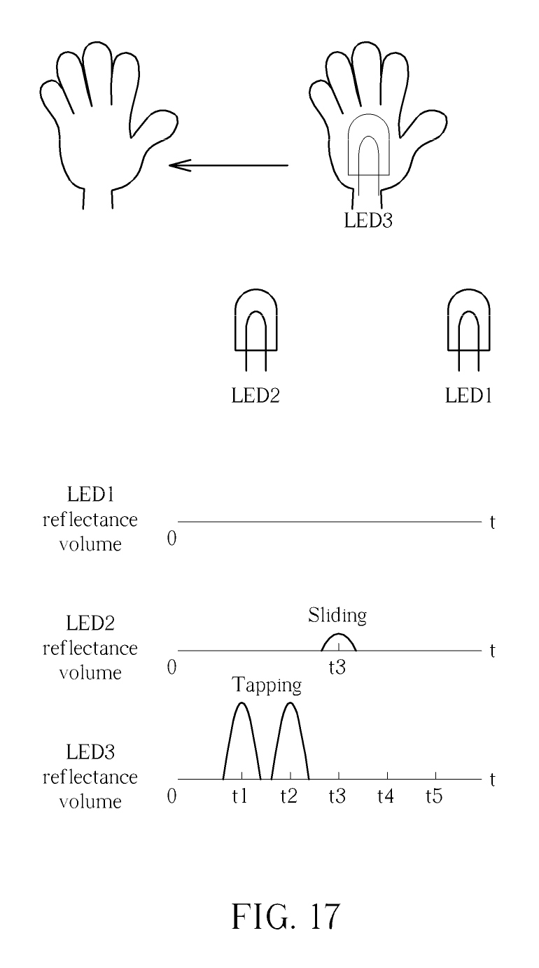

Please refer to FIG. 17, which is a diagram illustrating object detection and gesture recognition in the light sensor system 100 shown in FIG. 1 according to an embodiment of the present invention. As shown in FIG. 17, a hand tapping and sliding from right to left is detected and recognized by using a light emitter-light sensor set (LED1, LED2, LED 3 and the light sensor unit 120 (not shown in FIG. 17)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitter (the light emitter LED3). The sliding is recognized by the diminished signal strength over time associated with the origination light emitter location (the location corresponding to the light emitter LED3). In other words, the sliding is recognized by referring to the identified signal function of time indicating the occurrence sequence of the local peak levels of the light emitter LED3 and the light emitter LED2.

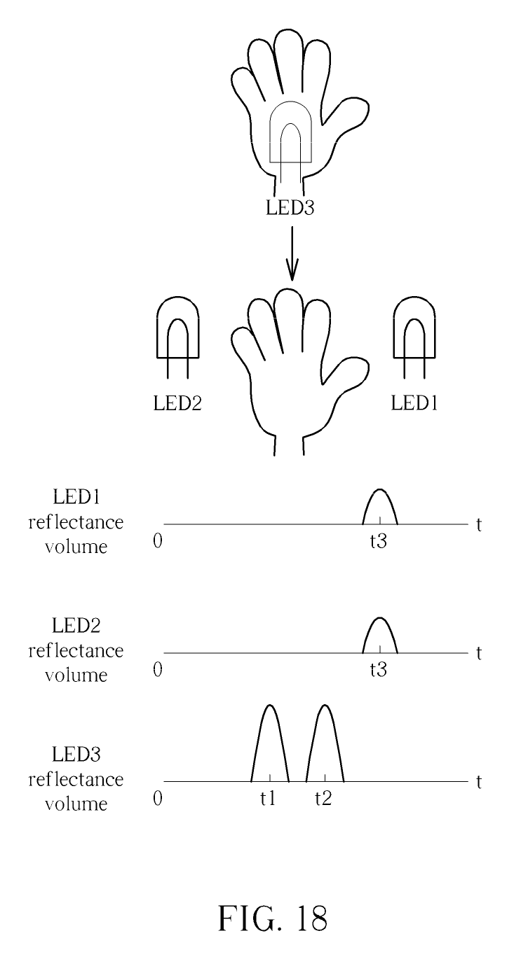

Please refer to FIG. 18, which is a diagram illustrating object detection and gesture recognition in the light sensor system 100 shown in FIG. 1 according to an embodiment of the present invention. As shown in FIG. 18, a hand tapping and sliding down is detected and recognized by using a light emitter-light sensor set (LED1, LED2, LED 3 and the light sensor unit 120 (not shown in FIG. 18)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitter (the light emitter LED3). The sliding is recognized by the diminished signal strength over time associated with the origination light emitter location (the location corresponding to the light emitter LED3) and the increased signal strength over time associated with the destination light emitters (i.e., light emitters LED1 and LED2). In other words, the sliding is recognized by referring to the identified signal function of time indicating the occurrence sequence of the local peak levels of the light emitters LED1-LED3.

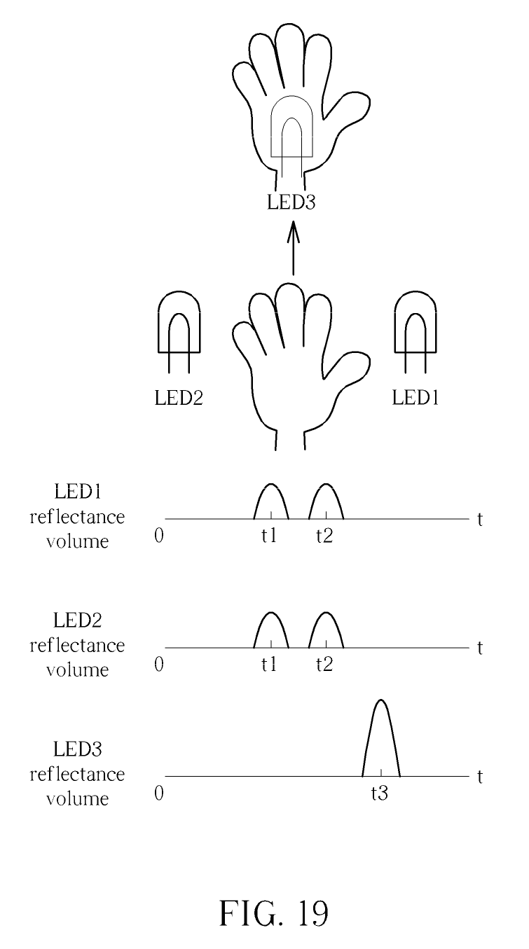

Please refer to FIG. 19, which is a diagram illustrating object detection and gesture recognition in the light sensor system 100 shown in FIG. 1 according to an embodiment of the present invention. As shown in FIG. 19, a hand tapping and sliding up is detected and recognized by using a light emitter-light sensor set (LED1, LED2, LED 3 and the light sensor unit 120 (not shown in FIG. 19)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitters (the light emitters LED1 and LED2). The sliding is recognized by the diminished signal strength over time associated with the origination light emitter locations (the locations corresponding to the light emitters LED1 and LED2) and the increased signal strength over time associated with the destination light emitter (light emitter LED3). In other words, the sliding is recognized by referring to the identified signal function of time indicating the occurrence sequence of the local peak levels of the light emitters LED1-LED3.

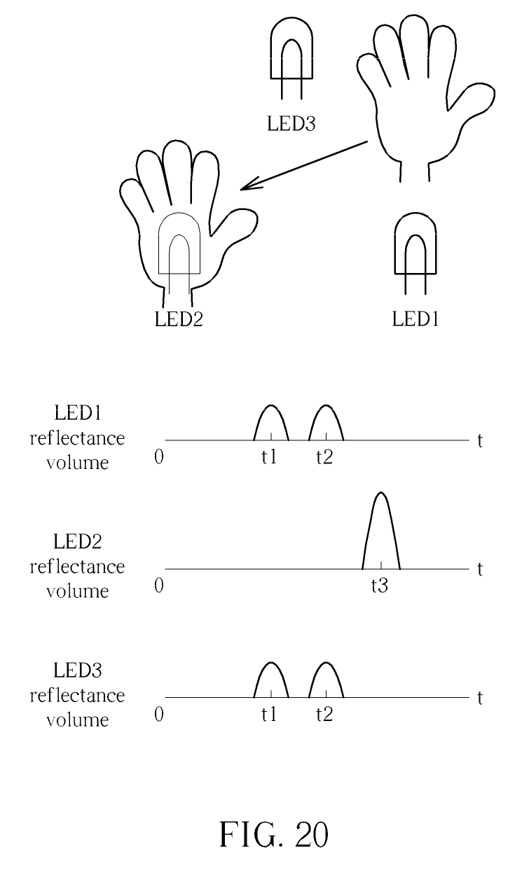

Please refer to FIG. 20, which is a diagram illustrating object detection and gesture recognition in the light sensor system 100 shown in FIG. 1 according to an embodiment of the present invention. As shown in FIG. 20, a hand tapping and sliding diagonally from upper right to lower left is detected and recognized by using a light emitter-light sensor set (LED1, LED2, LED 3 and the light sensor unit 120 (not shown in FIG. 20)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by the two similar peaks in signal strength at the origination light emitters (the light emitters LED1 and LED3). The sliding is recognized by the diminished signal strength over time associated with the origination light emitter locations (the locations corresponding to the light emitters LED1 and LED3) and the increased signal strength over time associated with the destination light emitter (light emitter LED2). In other words, the sliding is recognized by referring to the identified signal function of time indicating the occurrence sequence of the local peak levels of the light emitters LED1-LED3.

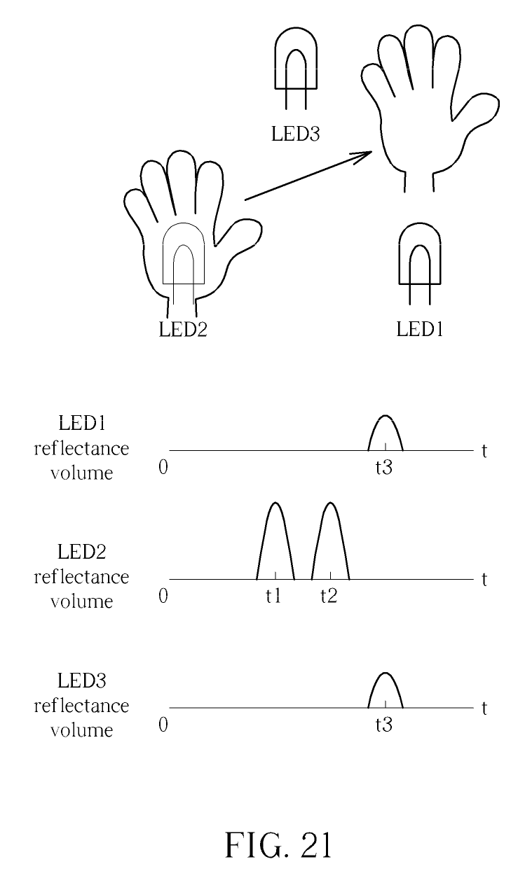

Please refer to FIG. 21, which is a diagram illustrating object detection and gesture recognition in the light sensor system 100 shown in FIG. 1 according to an embodiment of the present invention. As shown in FIG. 21, a hand tapping and sliding from lower left to upper right is detected and recognized by using a light emitter-light sensor set (LED1, LED2, LED 3 and the light sensor unit 120 (not shown in FIG. 21)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitter (the light emitter LED2). The sliding is recognized by the diminished signal strength over time associated with the origination light emitter location (the location corresponding to the light emitter LED2) and the increased signal strength over time associated with the destination light emitters (light emitters LED1 and LED3). In other words, the sliding is recognized by referring to the identified signal function of time indicating the occurrence sequence of the local peak levels of the light emitters LED1-LED3.

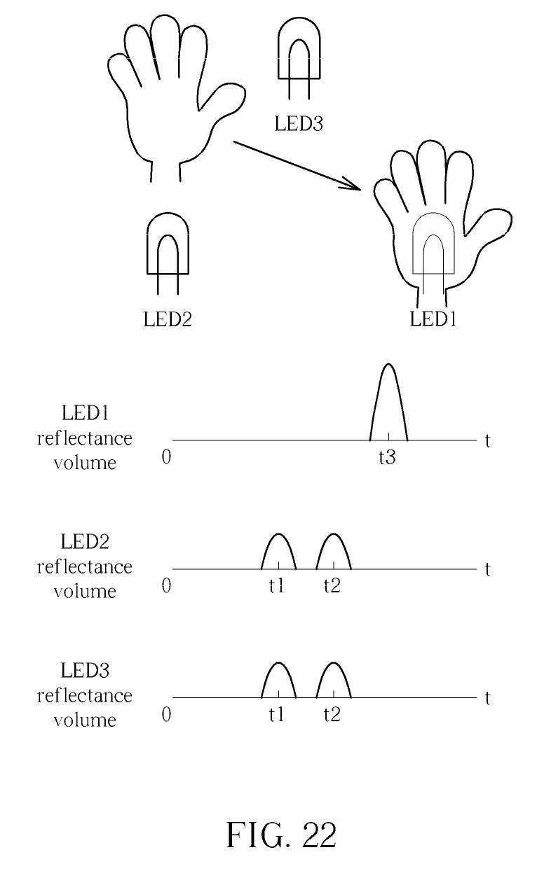

Please refer to FIG. 22, which is a diagram illustrating object detection and gesture recognition in the light sensor system 100 shown in FIG. 1 according to an embodiment of the present invention. As shown in FIG. 22, a hand tapping and sliding diagonally from upper left to lower right is detected and recognized by using a light emitter-light sensor set (LED1, LED2, LED 3 and the light sensor unit 120 (not shown in FIG. 22)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitters (the light emitters LED2 and LED3). The sliding is recognized by the diminished signal strength over time associated with the origination light emitter locations (the locations corresponding to the light emitters LED2 and LED3) and the increased signal strength over time associated with the destination light emitter (light emitter LED1). In other words, the sliding is recognized by referring to the identified signal function of time indicating the occurrence sequence of the local peak levels of the light emitters LED1-LED3.

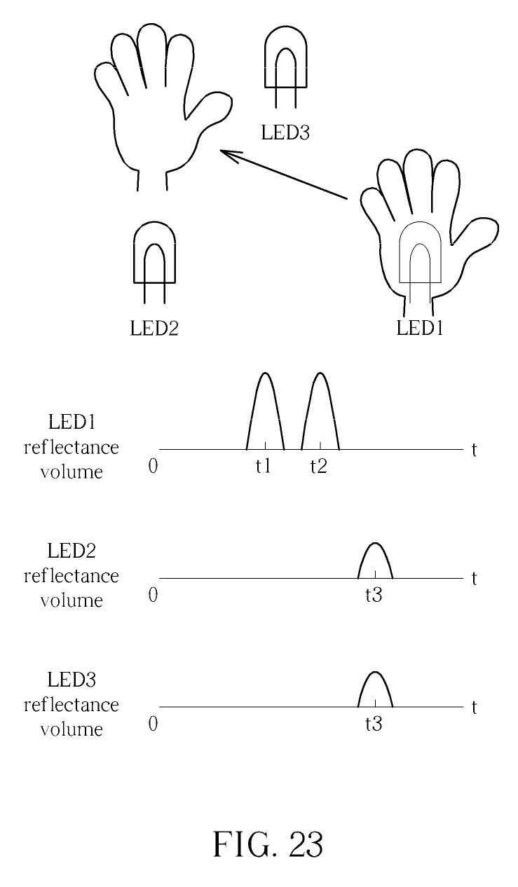

Please refer to FIG. 23, which is a diagram illustrating object detection and gesture recognition in the light sensor system 100 shown in FIG. 1 according to an embodiment of the present invention. As shown in FIG. 23, a hand tapping and sliding from lower right to upper left is detected and recognized by using a light emitter-light sensor set (LED1, LED2, LED 3 and the light sensor unit 120 (not shown in FIG. 23)). Each light emitter is lit one at a time, and reflectance volumes (signal levels of the reflected signals S_R1-S_Rn) are collected as the signal function of time, corresponding to each light emitter being lit. In this embodiment, the processing unit 130 may perform subsequent digital signal processing to recognize the hand gesture by referring to occurrence sequence of local peak levels in the time sequence. As mentioned above, the hand tapping is recognized by two similar peaks in signal strength at the origination light emitter (the light emitter LED1). The sliding is recognized by the diminished signal strength over time associated with the origination light emitter location (the location corresponding to the light emitter LED1) and the increased signal strength over time associated with the destination light emitters (light emitters LED2 and LED3). In other words, the sliding is recognized by referring to the identified signal function of time indicating the occurrence sequence of the local peak levels of the light emitters LED1-LED3.

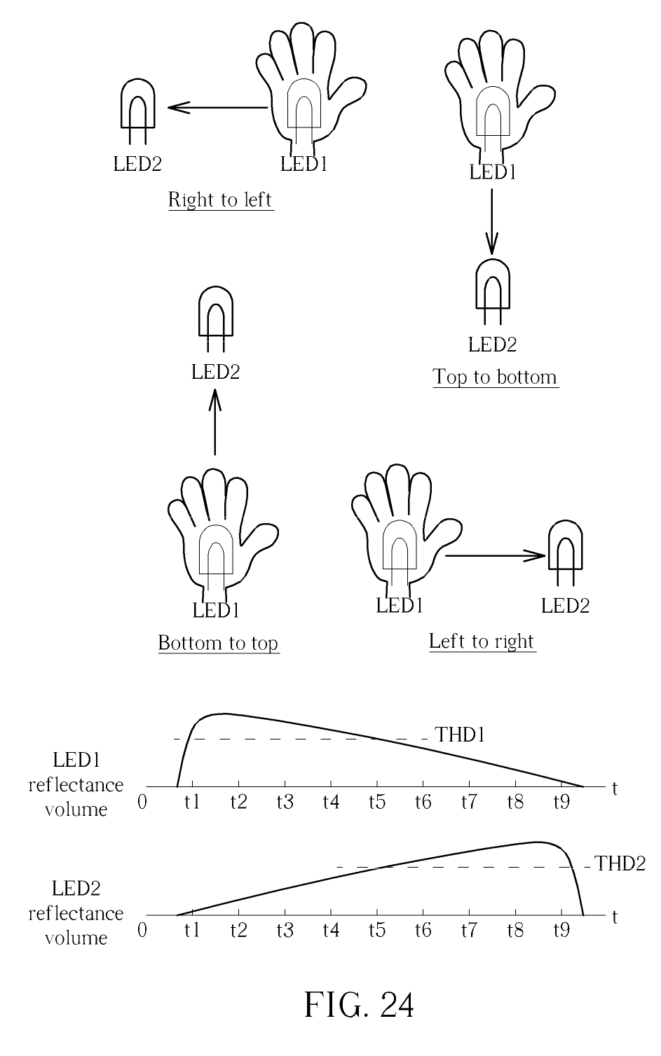

Please refer to FIG. 24, which is a diagram illustrating four straight movements corresponding to the same occurrence sequence of local peak levels in the light sensor system 100 shown in FIG. 1. As shown in FIG. 24, a sliding/scrolling hand gesture is detected and recognized in the X and Y directions (the horizontal and vertical directions), respectively. Specifically, the sliding/scrolling hand gesture is recognized by analyzing reflected signals taken as a signal function of time. The diminished signal strength over time is associated with the origination light emitter location (the light emitter LED1 or LED2, depending on the illustrated direction) and the increased signal strength over time is associated with the destination light emitter location (the light emitter LED1 or LED2, depending on the illustrated direction). In a preferred embodiment, the sampling rate of the reflected signals may be set much higher than the moving speed of the hand. In addition, it should be noted that identifying the signal function of time by referring to the occurrence sequence of the local peak levels is not a limitation of the present invention. In an alternative design, the signal function of time may be identified by comparing a predetermined threshold with signal levels of reflected signals.

Please refer to FIG. 3 in conjunction with FIG. 24. In a case where the processing unit 130 of the light sensor system 100 shown in FIG. 1 identifies the signal function of time by comparing a predetermined threshold with signal levels of the reflected signals S_R1-S_Rn, the processing unit 130 identifies the signal function of time by comparing a first predetermined threshold (e.g. a threshold THD1 shown in FIG. 24) with signal levels of the first reflected signals S_R11-S_R1n corresponding to the light emitter LED1 and comparing a second predetermined threshold (e.g. a threshold THD2 shown in FIG. 24) with signal levels of the second reflected signals S_R21-S_R2n corresponding to the light emitter LED2, and determines the motion of the object (e.g. the hand) by referring to the identified signal function of time. As shown in FIG. 3, a first reflected signal of the light emitter LED1 at a time t1 is detected above the first threshold set by the system software; then, a second reflected signal of the light emitter LED2 signal at a time t2 is detected above the second threshold while a first reflected signal of the light emitter LED1 at the time t2 goes below the first threshold. Please refer to FIG. 4 again. Similarly, in a case where the processing unit 130 of the light sensor system 100 shown in FIG. 1 identifies the signal function of time by comparing a predetermined threshold with signal levels of the reflected signals S_R1-S_Rn, the determination of hand motion shown in FIG. 4 may be summarized as follows: when the signal levels of the first reflected signals S_R11-S_R1n increase from below the first predetermined threshold to above the first predetermined threshold in the time sequence, and the signal levels of the second reflected signals S_R21-S_R2n decrease from above the second predetermined threshold to below the second predetermined threshold in the time sequence, the processing unit 130 may determine that the hand is moving from the light emitter LED2 toward the light emitter LED1. The predetermined thresholds are not shown in FIG. 3 (or in any of the figures in the instant application) but generally are calculated as known to those skilled in the art by using, for example, the signal levels of ambient light fluctuation and the crosstalk from the adjacent light emitters. Signal levels significantly above this predetermined threshold are deemed to be the result of a hand gesture.

Please refer to FIG. 1 again. In embodiments where the processing unit 130 of the light sensor system 100 identifies the signal function of time by comparing a predetermined threshold with signal levels of the reflected signals, the processing unit 130 may further recognize a gesture of the object OB_H corresponding to the motion of the object OB_H. In addition, in a case where the at least one light emitter 110 comprises a plurality of light emitters LED1-LEDr, the processing unit 130 may further control the light emitters LED1-LEDr to be activated alternately, and the time sequence is a sequence of time division frames. In an alternative design, the processing unit 130 may further control the light emitters LED1-LEDr to be simultaneously activated for emitting light beams with different wavelengths. In another alternative design, the light sensor unit 120 may include a plurality of light sensors (not shown in FIG. 1), which are dedicated to receiving reflected light corresponding to the light emitters, respectively. Moreover, the light sensor system 100 may further include a light barrier wall LBW formed between the at least one light emitter 110 and the light sensor unit 120, wherein the light barrier wall LBW is arranged to interrupt traveling of stray light emitted from the at least one light emitter 110.

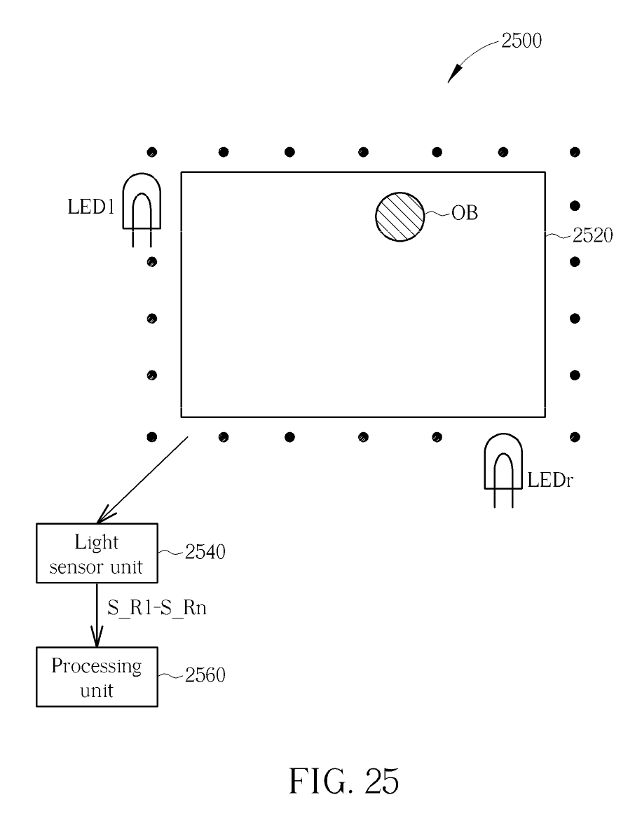

As mentioned above, a position of an object (e.g., a hand) may be obtained according to the local peak levels of the corresponding light emitters. Please refer to FIG. 25, which is a diagram illustrating another generalized light sensor system according to an embodiment of the present invention. The light sensor system 2500 includes, but is not limited to, a panel 2520, a plurality of light emitters LED1-LEDr, a light sensor unit 2540 and a processing unit 2560. In this embodiment, the light emitters LED1-LEDr are correspondingly disposed on a periphery of the panel 2520 for illustrative purposes only. The light sensor unit 2540 is arranged to receive reflected light from at least one object OB when the light emitters LED1-LEDr are activated, and accordingly output a plurality of reflected signals S_R1-S_Rn. The processing unit 2560 is arranged to receive the reflected signals S_R1-S_Rn and determine position of the at least one object OB on the panel 2520 by referring to local peak levels of the reflected signals S_R1-S_Rn. Please note that the local peak levels referred to by the processing unit 2560 correspond to peak signals in space, while the local peak levels mentioned in paragraphs directed to FIGS. 1-24 correspond to temporal peaks in the identified signal function of time. In one implementation, the processing unit 2560 may determine the position of the at least one object OB on the panel 2520 by referring to values of the local peak levels. In another implementation, the processing unit 2560 may determine the position of the at least one object OB on the panel 2520 by referring to positions of the light emitters LED1-LEDr corresponding to the local peak levels. In addition, the processing unit 2560 may further control the light emitters LED1-LEDr to be activated alternately. By way of example but not limitation, at least a portion of the light emitters LED1-LEDr may be divided into groups, and the processing unit 2560 may control the groups to be activated alternately. In an alternative design, the processing unit 2560 may further control the light emitters LED1-LEDr to be simultaneously activated for emitting light beams with different wavelengths. However, the above-mentioned activation configurations are for illustrative purposes only, and are not meant to be limitations of the present invention. In one embodiment, the processing unit 2560 may control the light emitters LED1-LEDr to be simultaneously activated for emitting light beams with the same wavelength, and the position of the at least one object OB may still be determined. Detailed description is given in the following.

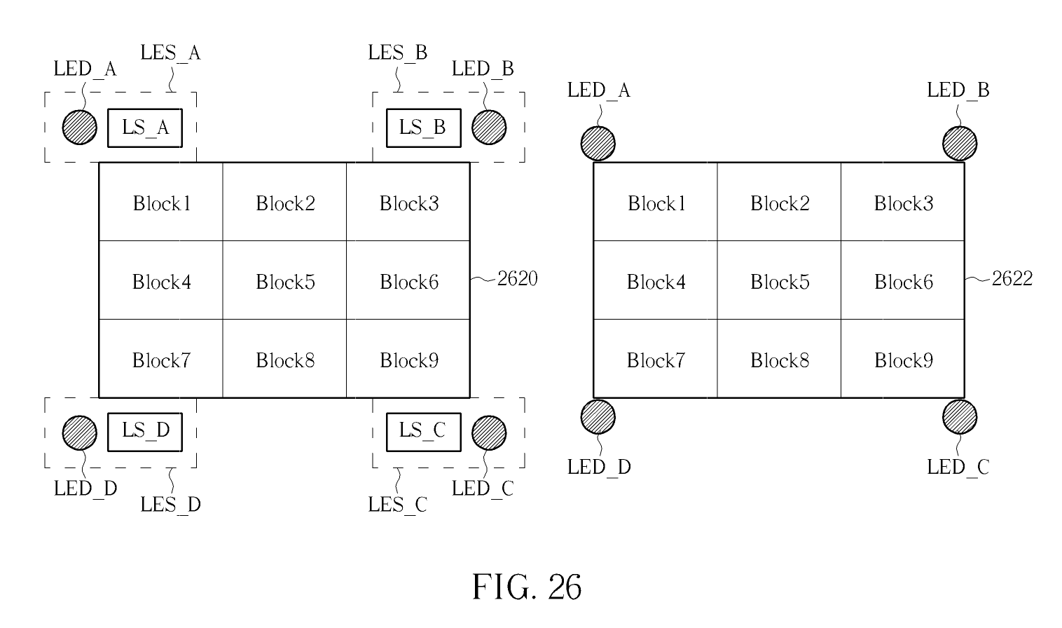

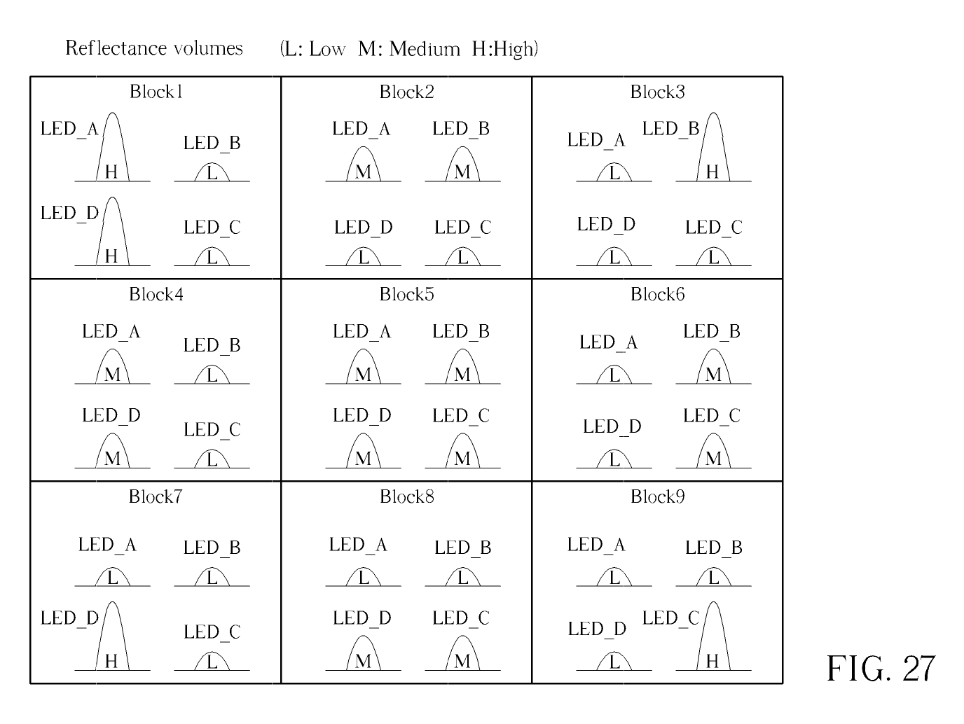

Please refer to FIG. 26 together with FIG. 27. FIG. 26 is a diagram illustrating exemplary configurations of light emitter-light sensor pairs and a light emitter-light sensor set over an exemplary screen/panel area represented by numbered blocks according to implementations of the light sensor system 2500 shown in FIG. 25, and FIG. 27 is a diagram illustrating exemplary reflectance volumes (or signal levels) of reflected signals corresponding to each of four light emitters LED_A-LED_D in each of the numbered blocks shown in the exemplary configurations of FIG. 26. In the left portion of FIG. 26, four light emitter-light sensor pairs LES_A-LES_D are correspondingly disposed at four corners of the panel 2520 shown in FIG. 25, and an area of the panel 2520 is represented by the numbered blocks Block1-Block9, wherein the four light emitter-light sensor pairs LES_A-LES_D include the light emitters LED_A-LED_D and light sensors LS_A-LS_D. In the right portion of FIG. 26, the four light emitters LED_A-LED_D are correspondingly disposed at four corners of the panel 2520, and the area of the panel 2520 is represented by the numbered blocks Block1-Block9, wherein the light emitter-light sensor set includes the light emitters LED_A-LED_D and a light sensor LS_S. The light sensor LS_S is located in proximity to the light emitters LED_A-LED_D (consistent with the remaining disclosure of the instant application) over the area of the panel 2520.

As will be appreciated by those skilled in the art, and consistent with the remaining disclosure of the instant application, the exemplary light emitter-light sensor pairs and light emitter-light sensor sets may be mixed or combined as desirable and the exemplary configurations are not meant to limit the scope of the instant disclosure.

As shown in FIG. 27, the reflectance volumes of reflected signals corresponding to each of the light emitters LED_A-LED_D in each of the numbered blocks Block1-Block9 may be expressed as high (H), medium (M) and low (L) levels. Those skilled in the art will recognize that, in the illustrated exemplary embodiment, a reflectance volume increases as the distance between the object (e.g. the hand) and the light sensor(s) decreases (an inverse relationship). However, as discussed elsewhere in the present disclosure, this relationship may be a direct relationship (the reflectance volume decreases as the distance decreases) without departing from the scope of the present invention.

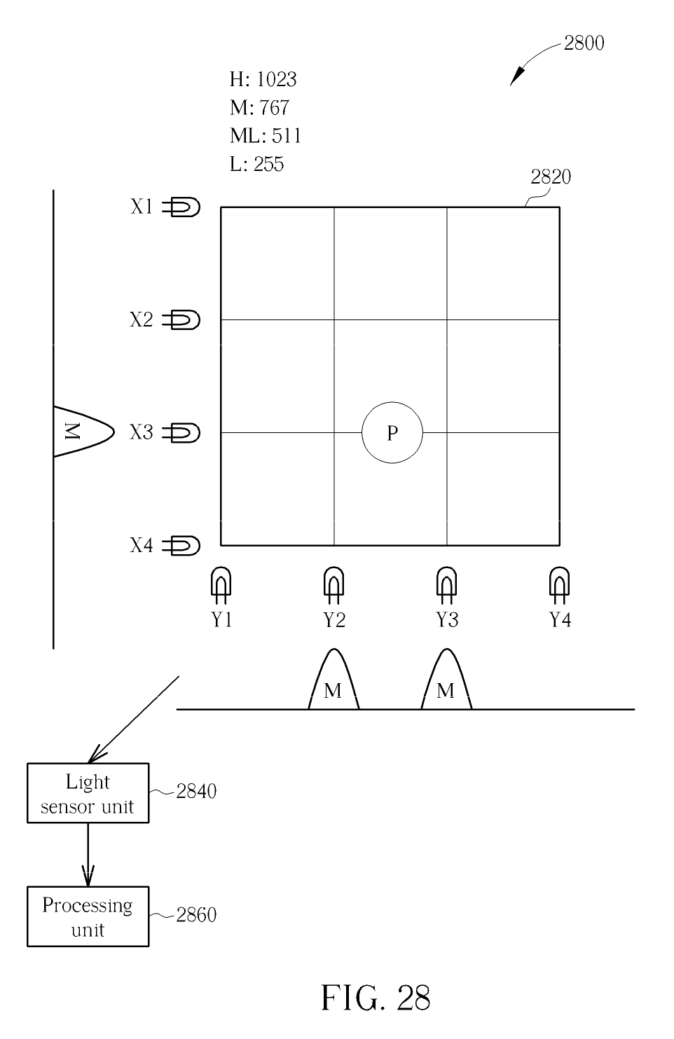

Please refer to FIG. 28, which is a diagram illustrating an exemplary light sensor system according to an implementation of the light sensor system 2500 shown in FIG. 25. The light sensor system 2800 includes, but is not limited to, a panel 2820 and a plurality of light emitters X1-X4 and Y1-Y4, a light sensor unit 2840 and a processing unit 2860. In this embodiment, the panel 2820 is of an exemplary 300×300 resolution, and the light emitters X1-X4 and Y1-Y4 are disposed along the edges and corners of the panel 2820. Reflection volumes (or signal levels) of the light emitters X1-X4 and Y1-Y4 are detected by a light sensor unit 2840. Exemplary values of high (H), medium (M), medium-low (ML) and low (L) reflectance volumes are shown in FIG. 28. The process of determining the location or position P of an object (e.g. a hand) on the panel 2820 is shown as follows.

In this embodiment, the processing unit 2860 determines the position of the object (e.g. the hand) on the panel 2820 by calculating a weighted calculation of values of the local peak levels, wherein weighting coefficients used in the weighted calculation are determined according to positions of the light emitters X1-X4 and Y1-Y4. More particularly, the position P may be obtained from the following calculations:

$$X - coordinate of the position P = ( \frac{{X}_{1} + 2 {X}_{2} + 3 {X}_{3} + 4 {X}_{4}}{{X}_{1} + {X}_{2} + {X}_{3} + {X}_{4}} - 1 ) \times RES + OST = ( \frac{0 + 2 \times 0 + 3 \times 767 + 4 \times 0}{0 + 0 + 767 + 0} - 1 ) \times 100 + 0 = 200$$

$$Y - coordinate of the position P = ( \frac{{Y}_{1} + 2 {Y}_{2} + 3 {Y}_{3} + 4 {Y}_{4}}{{Y}_{1} + {Y}_{2} + {Y}_{3} + {Y}_{4}} - 1 ) \times RES + OST = ( \frac{0 + 2 \times 767 + 3 \times 767 + 4 \times 0}{0 + 767 + 767 + 0} - 1 ) \times 100 + 0 = 150$$

The parameters X₁-X₄ correspond to the reflectance volumes of the light emitters X1-X4, and the parameters Y₁-Y₄ correspond to the reflectance volumes of the light emitters Y1-Y4. The parameter RES is determined according to the resolution corresponding to the panel 2820, and the parameter OST represents the signal offset. Using the above formula, the position along the X-axis can be calculated by analyzing the reflectance volumes of light emitters X1-X4. Similarly, the position along the Y-axis can be calculated by analyzing the reflectance volumes of light emitters Y1-Y4. The X-coordinate and Y-coordinate of the position P calculated in this manner represent the position P where the object (e.g. the hand) is located.

As further explained, each location on the panel 2820 (X-coordinate and Y-coordinate) has a light sensor signal associated with each of the light emitters correspondingly disposed along the X-axis and the Y-axis. A weighting coefficient is assigned to each light emitter, in the order of its X-axis and Y-axis coordinate (the distance to the corner where the light emitters X1 and Y1 intersect in this embodiment). The signal level associated with each light emitter is multiplied by the weighting coefficient and normalized by the total signal level of all the X-axis or Y-axis signals. The resulting calculation yields the X-coordinate and Y-coordinate of the hand location P in FIG. 28. The resolution of location P is a function of the light emitter pitch, the noise and the crosstalk of the signal.

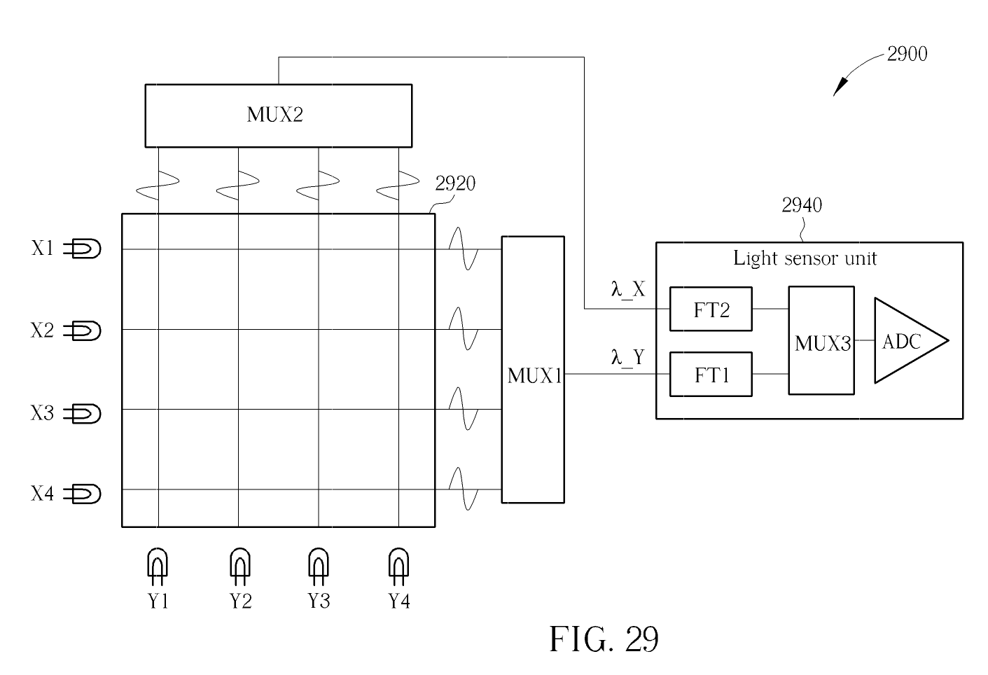

Please refer to FIG. 29, which is a diagram illustrating another exemplary light sensor system according to another implementation of the light sensor system 2500 shown in FIG. 25. The light sensor system 2900 includes, but is not limited to, a panel 2920, a plurality of light emitters X1-X4 and Y1-Y4, a light sensor unit 2940, and a plurality of multiplexers MUX1 and MUX2. The light sensor unit 2940 includes a plurality of filters FT1 and FT2, a multiplexer MUX3, and an analog-to-digital converter ADC. Specifically, FIG. 29 shows an embodiment in which the light emitters emit two light beams with different wavelengths in order to reduce the undesired crosstalk. Specifically, the light emitter emitters X1-X4 emit light beams with wavelength λ_X, while the light emitters Y1-Y4 emit light beams with wavelength λ_Y. Using two distinctive light spectrums for the light emitters X1-X4 and the light emitters Y1-Y4, and using the corresponding light sensor unit 2940 with narrow band wavelength filters (the filters FT1 and FT2) enable object detection by the light sensor unit 2940 of two reflectance volumes projected in the same space or area of the panel 2920. This embodiment, in particular, allows for enhanced X-Y and Z resolution of the three-dimensional (3D) screen pointing/hand gesture recognition. It will be appreciated by those skilled in the art that the multiplexers MUX1 and MUX2 are used to isolate the wavelengths λ_X and λ_Y before they pass through the filters FT1 and FT2 and arrive at the additional multiplexer MUX3 for separating the signals for analog-to-digital conversion.

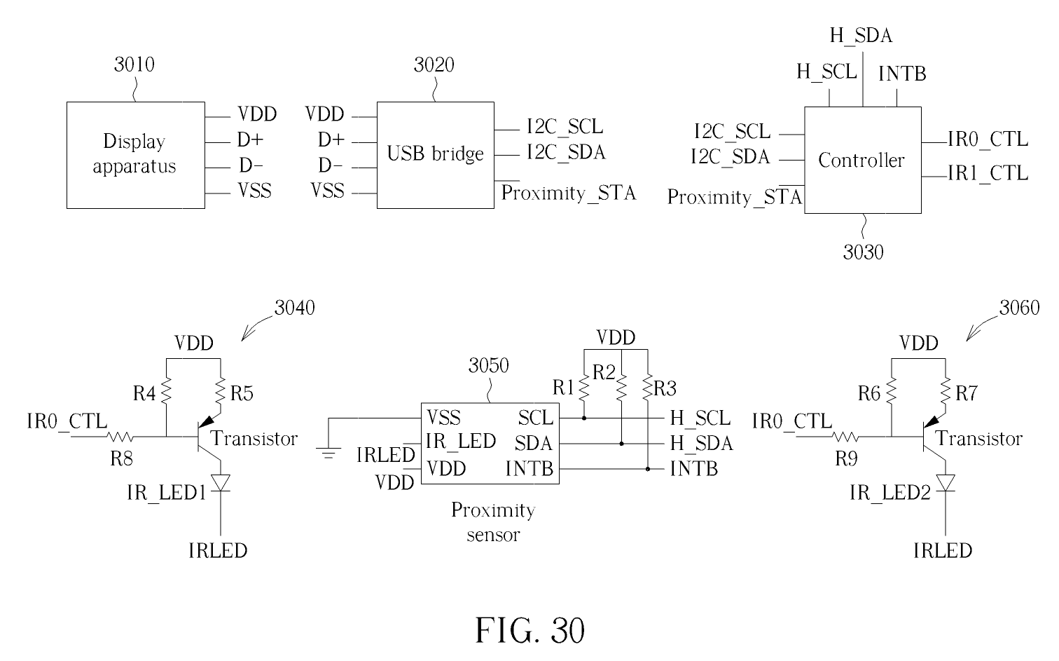

Please refer to FIG. 30, which is a diagram illustrating an exemplary IR emitter-proximity sensor set according to an embodiment of the present invention. As shown in FIG. 30, two IR emitters IR_LED1 and IR_LED2 are controlled by a controller 3030. A proximity sensor 3050 synchronizes the IR emitting duration for the IR emitters IR_LED1 and IR_LED2. The signal levels corresponding to the IR emitters IR_LED1 and IR_LED2 are collected one at a time. A coupling relationship between a display apparatus 3010, a Universal Serial Bus (USB) bridge 3020, the controller 3030, a first IR emitter circuit 3040, the proximity sensor 3050 and a second IR emitter circuit 3060 may be known from a plurality of connection nodes shown in FIG. 30. As a person skilled in the art can readily understand the operation of the light emitter-light sensor set through the coupling relationship, further description is omitted for brevity. In addition, multiple IR emitter-proximity sensor sets may be used for a single panel to enhance the resolution and scope of the space/screen where the hand gesture is intended to be detected and recognized.

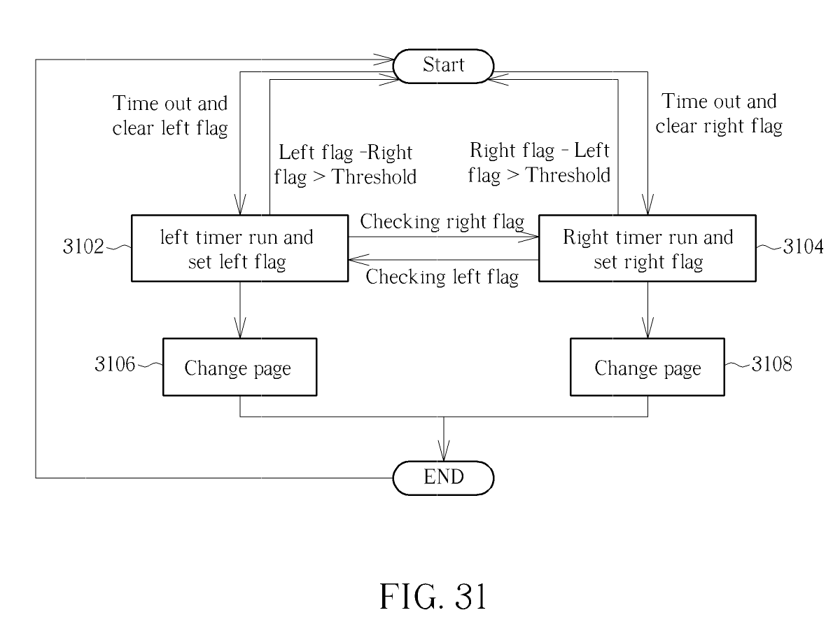

Please refer to FIG. 31, which is a flowchart of an exemplary application used to detect and recognizes hand gestures for the purpose of turning a page in a virtual book displayed on a screen according to an embodiment of the present invention. More particularly, the application detects and recognizes a hand moving from left to right (for example, turning the page of the book to advance forward in the book) and a hand moving from right to left (for example, turning the page of the book to move backward in the book). As shown in FIG. 31, at the “Start” of the process or method (or algorithm), a controller (e.g. a microcontroller) detects that the hand has initiated a sliding either from a right light emitter location or from a left light emitter location. The controller then proceeds to recognize that the sliding of the hand has occurred by referring to a signal function of time identified by comparing reflectance volumes associated with a right light emitter and a left light emitter (step 3102 and step 3104). When the reflectance volumes associated with the right light emitter and the left light emitter are reversed (i.e. a reflected signal corresponding to the left light emitter was high, but is now low, and a reflected signal corresponding to the right light emitter was low, but is now high, and vice-versa), the controller interprets the sliding hand gesture as the user wishing to turn the page of the book, and the controller will communicate these instructions accordingly (step 3106 and step 3108). The detection/recognition of an object (close to the left light emitter) is initialized after the timeout, and the flow clears a left flag corresponding to the left light emitter, which activates a left timer and sets the left flag. When the difference between the left flag and the right flag is less than a threshold, the flow will execute the step 3106. In addition, at the “End” of the process or method (or algorithm), the controller may wait a period of time before the flow restarts, and all flags are cleared. Those skilled in the art will recognize that this application is but one example of the use of the light sensor system and object detection method of the present invention, and all applications of the light sensor system and object detection method of the present invention are included within the scope of the present disclosure.

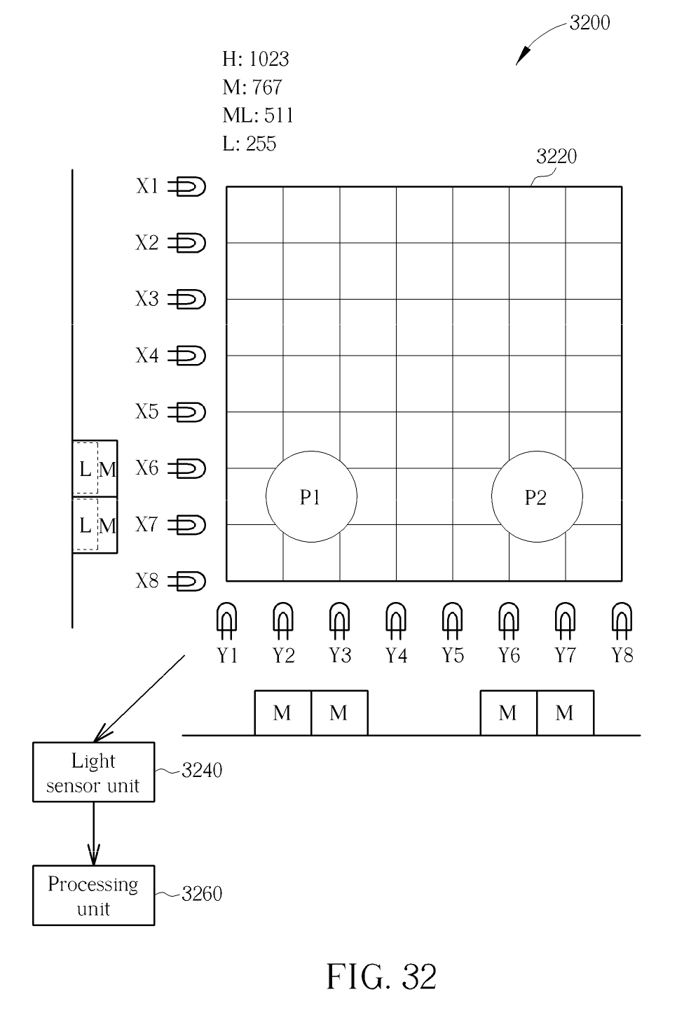

Please refer to FIG. 32, which is a diagram illustrating another exemplary light sensor system according to another implementation of the light sensor system 2500 shown in FIG. 25. The light sensor system 3200 includes, but is not limited to, a panel 3220 and a plurality of light emitters X1-X8 and Y1-Y8, a light sensor unit 3240 and a processing unit 3260. In this embodiment, the panel 3220 is of an exemplary 700×700 resolution, and the light emitters X1-X8 and Y1-Y8 are disposed along the edges and corners of the panel 3220. Reflection volumes (or signal levels) of the light emitters X1-X8 and Y1-Y8 are detected by a light sensor unit 3240. Exemplary values of high (H), medium (M), medium-low (ML) and low (L) reflectance volumes are shown in FIG. 32. The process of determining the locations or positions P1 and P2 of an object (e.g. a hand) on the panel 3220 is detailed as follows.

In this embodiment, the processing unit 3260 determines the positions P1 and P2 of the object (e.g., the hand) on the panel 3220 by calculating a weighted calculation of values of the local peak levels, wherein weighting coefficients used in the weighted calculation are determined according to positions of the light emitters X1-X8 and Y1-Y8. More particularly, the positions P1 and P2 may be obtained from the following calculations:

$$X - coordinate of the position P 1 = ( \frac{{X}_{1} + 2 {X}_{2} + 3 {X}_{3} + 4 {X}_{4} + 5 {X}_{5} + 6 {X}_{6} + 7 {X}_{7} + 8 {X}_{8}}{{X}_{1} + {X}_{2} + {X}_{3} + {X}_{4} + {X}_{5} + {X}_{6} + {X}_{7} + {X}_{8}} - 1 ) \times RES + OST = ( \frac{0 + 2 \times 0 + 3 \times 0 + 4 \times 0 + 5 \times 0 + 6 \times 767 + 7 \times 767 + 8 \times 0}{0 + 0 + 0 + 0 + 0 + 767 + 767 + 0} - 1 ) \times 100 + 0 = 550$$

$$X - coordinate of the position P 2 = ( \frac{{X}_{1} + 2 {X}_{2} + 3 {X}_{3} + 4 {X}_{4} + 5 {X}_{5} + 6 {X}_{6} + 7 {X}_{7} + 8 {X}_{8}}{{X}_{1} + {X}_{2} + {X}_{3} + {X}_{4} + {X}_{5} + {X}_{6} + {X}_{7} + {X}_{8}} - 1 ) \times RES + OST = ( \frac{0 + 2 \times 0 + 3 \times 0 + 4 \times 0 + 5 \times 0 + 6 \times 255 + 7 \times 255 + 8 \times 0}{0 + 0 + 0 + 0 + 0 + 255 + 255 + 0} - 1 ) \times 100 + 0 = 550$$

$$Y - coordinate of the position P 1 = ( \frac{{Y}_{1} + 2 {Y}_{2} + 3 {Y}_{3} + 4 {Y}_{4} + 5 {Y}_{5} + 6 {Y}_{6} + 7 {Y}_{7} + 8 {Y}_{8}}{{Y}_{1} + {Y}_{2} + {Y}_{3} + {Y}_{4} + {Y}_{5} + {Y}_{6} + {Y}_{7} + {Y}_{8}} - 1 ) \times RES + OST = ( \frac{0 + 2 \times 767 + 3 \times 767 + 4 \times 0 + 5 \times 0 + 6 \times 0 + 7 \times 0 + 8 \times 0}{0 + 767 + 767 + 0 + 0 + 0 + 0 + 0} - 1 ) \times 100 + 0 = 150$$

$$Y - coordinate of the position P 2 = ( \frac{{Y}_{1} + 2 {Y}_{2} + 3 {Y}_{3} + 4 {Y}_{4} + 5 {Y}_{5} + 6 {Y}_{6} + 7 {Y}_{7} + 8 {Y}_{8}}{{Y}_{1} + {Y}_{2} + {Y}_{3} + {Y}_{4} + {Y}_{5} + {Y}_{6} + {Y}_{7} + {Y}_{8}} - 1 ) \times RES + OST = ( \frac{0 + 2 \times 0 + 3 \times 0 + 4 \times 0 + 5 \times 0 + 6 \times 767 + 7 \times 767 + 8 \times 0}{0 + 0 + 0 + 0 + 0 + 767 + 767 + 0} - 1 ) \times 100 + 0 = 550$$

The parameters X₁-X₈ correspond to the reflectance volumes of the light emitters X1-X8, and the parameters Y₁-Y₈ correspond to the reflectance volumes of the light emitters Y1-Y8. The parameter RES is determined according to the resolution corresponding to the panel 3220, and the parameter OST represents the signal offset. Using the above formula (similar to the formula and logic as discussed with respect to FIG. 28), the position along the X-axis can be calculated by analyzing the reflectance volumes of light emitters X1-X8. Please note that, as the above weighted calculation is used to fine out peaks of the reflected signals, the X-coordinate of the position P2 may be obtained with the peak values corresponding to the position P1. The calculation shown in FIG. 32 may be done once for the X-axis.

Similarly, the position along the Y-axis can be calculated by analyzing the reflectance volumes of light emitters Y1-Y8. However, because the Y-axis has two separate points, a threshold is applied to the signal corresponding to the light emitters Y1-Y8 in order to detect that there are two groups of adjacent signals which exceed the threshold (one for the position P1 (the light emitters Y2 and Y3) and one for the position P2 (the light emitters Y6 and Y7)). Thus, the calculation shown in FIG. 32 is done twice for the Y-axis. At each calculation, one group of signals is artificially set to be zero in order to allow the calculation of the coordinates for the other group. The reflected signals corresponding to the light emitters Y2 and Y3 are artificially set to zero while the reflected signals corresponding to the light emitters Y6 and Y7 are analyzed, and vice-versa. The X-coordinates and Y-coordinates of the positions P1 and P2 calculated in this manner represent the positions P1 and P2 where the hands are located. In brief, the Y-coordinates of the positions P1 and P2 along the same horizontal line (e.g. a horizontal line corresponding to the light emitter X3 or X4) may be determined by referring to positions of the light emitters Y1-Y8 corresponding to detected local peak levels. In addition, the X-coordinates of the positions P1 and P2 along the same horizontal line (e.g. a horizontal line corresponding to the light emitter X3 or X4) may be determined by referring to values of detected local peak levels.

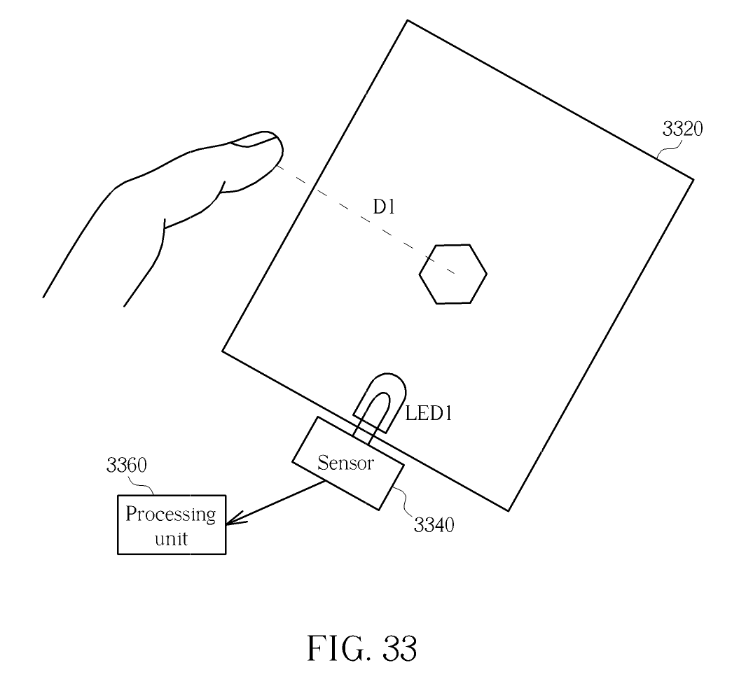

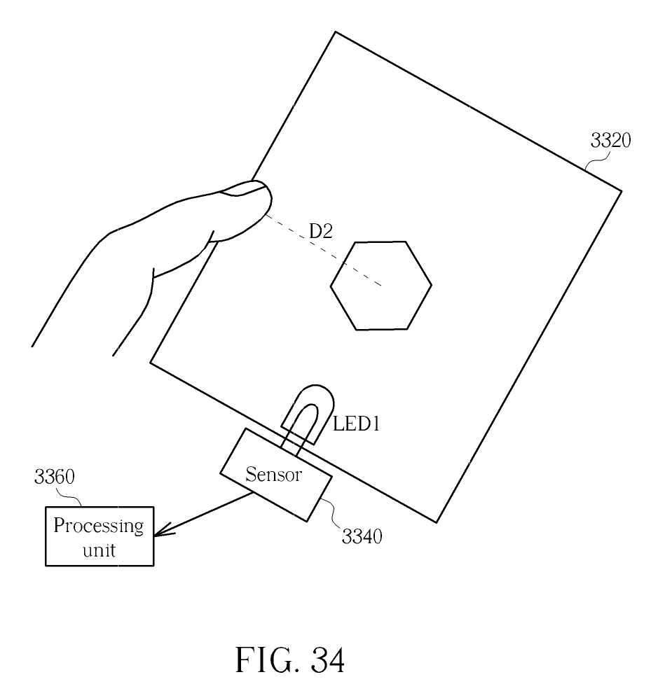

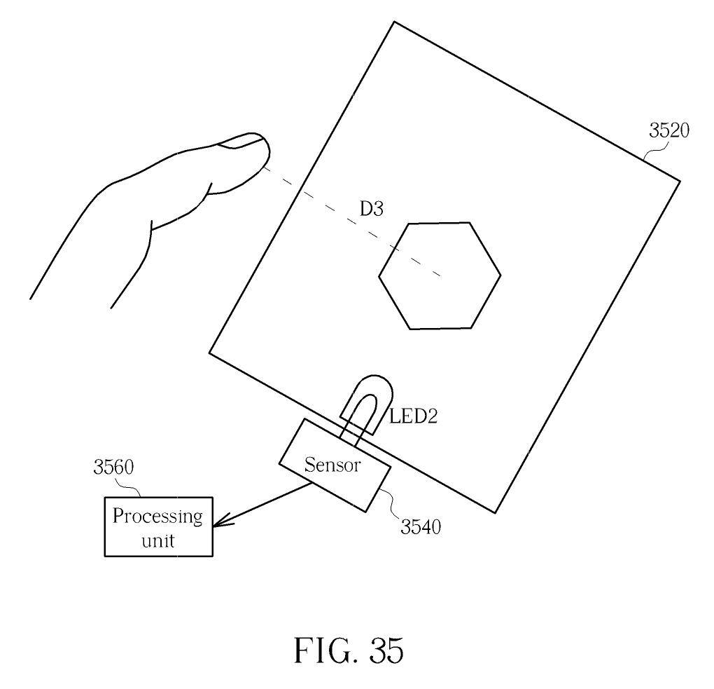

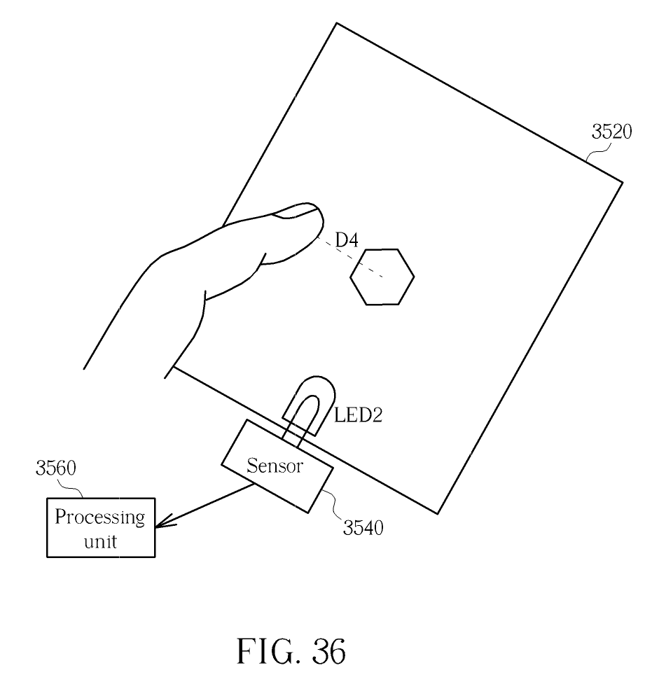

Please refer to FIGS. 33-36. FIG. 33 is a diagram illustrating hand detection and gesture recognition in the light sensor system 100 shown in FIG. 1 according to an embodiment of the present invention, and FIG. 34 is a diagram illustrating hand detection and gesture recognition shown in FIG. 33 at a later point in time. FIG. 35 is a diagram illustrating hand detection and gesture recognition in the light sensor system 100 shown in FIG. 1 according to an embodiment of the present invention, and FIG. 36 is a diagram illustrating hand detection and gesture recognition shown in FIG. 35 at a later point in time. In these embodiments, a signal function of time is identified by comparing a predetermined threshold with signal levels of reflected signals S_R1-S_Rn, and motion of a hand is determined by referring to the signal function of time. As show in FIGS. 33-36, a hand gesture can be detected and recognized in the Z direction (e.g. a direction perpendicular to a plane of a panel 3320/3520) for the purposes of initiating a new hand gesture recognition process (such as for zooming in and out of the panel 3320/3520). A hand (or other body part, or an object) can be held in front of the panel 3320/3520 (or a screen) steadily for a set period of time (such as two seconds) in order to initiate a new gesture recognition process. Then the hand can move closer to the panel 3320/3520 and stop for a set period of time (such as two seconds) again in order to end the process. This is an example showing how a Z-movement direction can be recognized as a hand gesture. In brief, a processing unit 3360/3560 may further detect if the signal levels of the reflected signals S_R1-S_Rn remain unchanged for a predetermined time period, and the processing unit 3360/3560 may start determining the motion of the hand after it is detected that the signal levels are unchanged for the predetermined time period. In addition, the processing unit 3360/3560 may further detect if the signal levels of the reflected signals S_R1-S_Rn remain unchanged for a predetermined time period, and the processing unit 3360/3560 may stop determining the motion of the hand after it is detected that the signal levels are unchanged for the predetermined time period.

In these embodiments, when the signal levels of the reflected signals S_R1-S_Rn increase from below a predetermined threshold to above the predetermined threshold in the time sequence, the processing unit 3360/3560 may determine that the hand is moving toward a light emitter LED1/LED2. Additionally, when the signal levels of the reflected signals S_R1-S_Rn decrease from above a predetermined threshold to below the predetermined threshold in the time sequence, the processing unit 3360/3560 may determine that the hand is moving away from the light emitter LED1/LED2. The application of this process is shown in FIGS. 33-36. In FIG. 33, a hand is held steady at a Z-distance D1 for a set period of time to initiate a Z-movement gesture recognition. In FIG. 34, as the hand moves closer to the screen, a Z-distance D2 becomes smaller than the Z-distance D1 over time. This is interpreted as a request to zoom in on the panel 3320. In FIG. 35, the hand again is held at a steady Z-distance D3 for a set period of time to start the Z-movement gesture recognition. In FIG. 36, the subsequent movement of the hand causes a Z-distance D4 to become smaller than Z-distance D3 over time. This is interpreted as a request to zoom out on the screen. Those skilled in the art will recognize other uses that can be made for this Z-movement gesture recognition application, all of which are within the scope of the instant disclosure.

In another embodiment of the Z-movement gesture recognition application using the light sensor system and object detection method of the present invention, instead of holding the hand steady for a predetermined time period to initiate and stop the Z-movement gesture recognition, a user can wave the hand in the same Z distance for a predetermined time period, assuming there are multiple light emitters in the configuration.

All patents referred to herein are hereby incorporated by reference. In the present disclosure, the words “a” or “an” are to be taken to include both the singular and the plural. Conversely, any reference to plural items shall, where appropriate, include the singular.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light sensor system, comprising:
at least one light emitter;
a light sensor unit, for receiving reflected light from an object in accordance with a time sequence in which the at least one light emitter is activated, and accordingly outputting a plurality of reflected signals; and
a processing unit, for receiving the reflected signals, identifying a signal function of time by comparing a predetermined threshold with signal levels of the reflected signals, and determining motion of the object by referring to the signal function of time.

2. The light sensor system of claim 1, wherein the processing unit further recognizes a gesture of the object corresponding to the motion of the object.

3. The light sensor system of claim 1, wherein the processing unit further detects if the signal levels of the reflected signals remain unchanged for a predetermined time period, and the processing unit starts determining the motion of the object after it is detected that the signal levels are unchanged for the predetermined time period.

4. The light sensor system of claim 1, wherein the processing unit further detects if the signal levels of the reflected signals remain unchanged for a predetermined time period, and the processing unit stops determining the motion of the object after it is detected that the signal levels are unchanged for the predetermined time period.

5. The light sensor system of claim 1, wherein when the signal levels of the reflected signals increase from below the predetermined threshold to above the predetermined threshold in the time sequence, the processing unit determines that the object is moving toward the at least one light emitter.

6. The light sensor system of claim 1, wherein when the signal levels of the reflected signals decrease from above the predetermined threshold to below the predetermined threshold in the time sequence, the processing unit determines that the object is moving away from the at least one light emitter.

7. The light sensor system of claim 1, wherein the at least one light emitter comprises a plurality of light emitters, and the processing unit further controls the light emitters to be activated alternately, and the time sequence is a sequence of time division frames.

8. The light sensor system of claim 1, wherein the at least one light emitter comprises a plurality of light emitters, and the processing unit further controls the light emitters to be simultaneously activated for emitting light beams with different wavelengths.

9. The light sensor system of claim 1, wherein the at least one light emitter comprises a plurality of light emitters, and the light sensor unit comprises:
a plurality of light sensors, dedicated to receiving reflected light corresponding to the light emitters, respectively.

10. The light sensor system of claim 1, wherein the at least one light emitter comprises a first light emitter and a second light emitter; the reflected signals generated from the light sensor unit include a plurality of first reflected signals corresponding to the first light emitter and a plurality of second reflected signals corresponding to the second light emitter; and the processing unit identifies the signal function of time by comparing a first predetermined threshold with signal levels of the first reflected signals and comparing a second predetermined threshold with signal levels of the second reflected signals, and determines the motion of the object by referring to the identified signal function of time.

11. The light sensor system of claim 10, wherein when the signal levels of the first reflected signals increase from below the first predetermined threshold to above the first predetermined threshold in the time sequence, and the signal levels of the second reflected signals decrease from above the second predetermined threshold to below the second predetermined threshold in the time sequence, the processing unit determines that the object is moving from the second light emitter toward the first light emitter.

12. The light sensor system of claim 1, further comprising:
a light barrier wall, formed between the at least one light emitter and the light sensor unit, for interrupting traveling of stray light emitted from the at least one light emitter.

13. A light sensor system, comprising:
at least one light emitter;
a light sensor unit, for receiving reflected light from an object in accordance with a time sequence in which the at least one light emitter is activated, and accordingly outputting a plurality of reflected signals; and
a processing unit, for receiving the reflected signals, identifying a signal function of time by referring to occurrence sequence of local peak levels of the reflected signals, and determining motion of the object according to the signal function of time.

14. The light sensor system of claim 13, wherein the processing unit further recognizes a gesture of the object corresponding to the motion of the object.

15. The light sensor system of claim 13, wherein the at least one light emitter comprises a plurality of light emitters, and the processing unit further controls the light emitters to be activated alternately, and the time sequence is a sequence of time division frames.

16. The light sensor system of claim 13, wherein the at least one light emitter comprises a plurality of light emitters, and the processing unit further controls the light emitters to be simultaneously activated for emitting light beams with different wavelengths.

17. The light sensor system of claim 13, wherein the at least one light emitter comprises a plurality of light emitters, and the light sensor unit comprises:
a plurality of light sensors, dedicated to receiving reflected light corresponding to the light emitters, respectively.

18. The light sensor system of claim 13, wherein the at least one light emitter comprises a first light emitter and a second light emitter; the reflected signals generated from the light sensor unit include a plurality of first reflected signals corresponding to the first light emitter and a plurality of second reflected signals corresponding to the second light emitter; and the processing unit identifies the signal function of time by referring to occurrence sequence of local peak levels of the first and the second reflected signals, and determines the motion of the object by referring to the identified signal function of time.

19. The light sensor system of claim 18, wherein when the identified signal function of time indicates that a local peak level of the first reflected signals occurs before a local peak level of the second reflected signals, the processing unit determines that the object is moving from the first light emitter toward the second light emitter.

20. The light sensor system of claim 13, wherein the at least one light emitter comprises a first light emitter, a second light emitter and a third light emitter; the reflected signals generated from the light sensor unit include a plurality of first reflected signals corresponding to the first light emitter, a plurality of second reflected signals corresponding to the second light emitter and a plurality of third reflected signals corresponding to the third light emitter; and the processing unit identifies the signal function of time by referring to occurrence sequence of local peak levels of the first, the second and the third reflected signals, and determines the motion of the object by referring to the identified signal function of time.

21. The light sensor system of claim 20, wherein when the identified signal function of time indicates that local peak levels of the first, the third, and the second reflected signals occur in sequence in the time sequence, the processing unit determines that the object is moving from the first light emitter toward the second light emitter through the third light emitter.

22. The light sensor system of claim 21, wherein the processing unit further compares a predetermined level with the local peak levels of the first, the third, and the second reflected signals, and determines that the object has a circular movement when each of the local peak levels of the first, the third, and the second reflected signals is higher than the predetermined level.

23. The light sensor system of claim 21, wherein the processing unit further compares a predetermined level with the local peak levels of the first, the third, and the second reflected signals, and determines that the object has a straight movement when at least one of the local peak levels of the first, the third, and the second reflected signals is lower than the predetermined level.

24. The light sensor system of claim 20, wherein when the identified signal function of time indicates that local peak levels of the first and the second reflected signals occur substantially at a same time immediately after occurrence of a local peak level of the third reflected signals, the processing unit determines that the object is moving from the third light emitter toward a position between the first and the second light emitters.

25. The light sensor system of claim 20, wherein when the identified signal function of time indicates that local peak levels of the first and the second reflected signals occur substantially at a same time immediately before occurrence of a local peak level of the third reflected signals, the processing unit determines that the object is moving from a position between the first and the second emitters toward the third emitter.

26. The light sensor system of claim 13, wherein when the identified signal function indicates that the local peak levels of the reflected signals have substantially a same magnitude and occur sequentially, the processing unit determines that the object is moving to and fro with respect to the at least one light emitter.

27. The light sensor system of claim 26, wherein the processing unit further refers to a number of the local peak levels to determine a number of times the object is moving to and fro with respect to the at least one light emitter.

28. The light sensor system of claim 13, further comprising:
a light barrier wall, formed between the at least one light emitter and the light sensor unit, for interrupting traveling of stray light emitted from the at least one light emitter.

29. A light sensor system, comprising:
a panel;
a plurality of light emitters;
a light sensor unit, for receiving reflected light from at least one object when the light emitters are activated, and accordingly outputting a plurality of reflected signals; and
a processing unit, for receiving the reflected signals and determining position of the at least one object on the panel by referring to local peak levels of the reflected signals.

30. The light sensor system of claim 29, wherein the processing unit determines the position of the at least one object on the panel by referring to values of the local peak levels.

31. The light sensor system of claim 29, wherein the processing unit determines the position of the at least one object on the panel by referring to positions of the light emitters corresponding to the local peak levels.

32. The light sensor system of claim 29, wherein the processing unit determines the position of the at least one object on the panel by calculating a weighted calculation of values of the local peak levels, wherein weighting coefficients used in the weighted calculation are determined according to positions of the light emitters.

33. The light sensor system of claim 29, wherein the processing unit further controls the light emitters to be activated alternately.

34. The light sensor system of claim 29, wherein the processing unit further controls the light emitters to be simultaneously activated for emitting light beams with different wavelengths.

35. An object detection method, comprising:
receiving reflected light from an object in accordance with a time sequence in which at least one light emitter is activated, and accordingly outputting a plurality of reflected signals;
identifying a signal function of time by comparing a predetermined threshold with signal levels of the reflected signals; and
determining motion of the object by referring to the signal function of time.

36. The object detection method of claim 35, further comprising:
recognizing a gesture of the object corresponding to the motion of the object.

37. An object detection method, the method comprising:
receiving reflected light from an object in accordance with a time sequence in which at least one light emitter is activated, and accordingly outputting a plurality of reflected signals;
identifying a signal function of time by referring to occurrence sequence of local peak levels of the reflected signals; and
determining motion of the object according to the signal function of time.

38. The object detection method of claim 37, further comprising:
recognizing a gesture of the object corresponding to the motion of the object.
